(19) United States
(12) Patent Application Publication
(10) Pub. No.: US 2022/0264045 A1
(43) Pub. Date: Aug. 18, 2022

(54) SOLID-STATE IMAGING ELEMENT, IMAGING APPARATUS, AND METHOD OF CONTROLLING SOLID-STATE IMAGING ELEMENT

(71) Applicant: SONY SEMICONDUCTOR SOLUTIONS CORPORATION, KANAGAWA (JP)

(72) Inventor: SHINYA MIYATA, KANAGAWA (JP)

(21) Appl. No.: 17/624,801

(22) PCT Filed: Jun. 1, 2020
(86) PCT No.: PCT/JP2020/021515

§ 371 Date: Jan. 4, 2022

(30) Foreign Application Priority Data
Jul. 18, 2019 (JP) 2019-132743

(51) Int. Cl. H04N 5/3745; H04N 5/378; H04N 5/376

(52) U.S. Cl. CPC H04N 5/3745; H04N 5/376; H04N 5/378

(57) ABSTRACT

A processing speed is improved in a solid-state imaging element that performs signal processing on a part of image data.

A repeater is connected to a cluster in which a predetermined number of pixels are arrayed and transfers digital signals indicating a time within a predetermined period. A comparator compares an analog signal corresponding to an amount of exposure with a reference signal varying during the predetermined period and outputs a comparison result. A latch circuit acquires the digital signal from the repeater and holds the digital signal. A latch control circuit controls the latch circuit to cause the latch circuit to hold the digital signal when the comparison result is inverted and controls the latch circuit to cause the latch circuit to output the digital signal to the repeater at a timing indicated by a predetermined output timing signal. An enable control unit supplies the output timing signal to the latch control circuit in a case where output of the digital signal is set to be enabled in response to a predetermined output enable signal.

### TECHNICAL FIELD

The present technology relates to a solid-state imaging element. More specifically, the present technology relates to a solid-state imaging element that simultaneously exposes all pixels, an imaging apparatus, and a method of controlling the solid-state imaging element.

### BACKGROUND ART

In order to, for example, capture an image of a fast-moving subject, a global shutter method of simultaneously exposing all pixels has been conventionally used in a solid-state imaging element in consideration of an advantage of not causing rolling shutter distortion. For example, there is proposed a solid-state imaging element in which a pixel circuit and an analog to digital converter (ADC) are arranged for each pixel and a drive circuit simultaneously exposes all pixels to output digital signals (see, for example, Patent Document 1). In order to perform signal processing only on a part of image data in the solid-state imaging element, a repeater transfers digital signals from pixels to be processed to a signal processing unit in the unit of rows, and the signal processing unit extracts the digital signals to be processed in the unit of columns and performs the signal processing.

### CITATION LIST

### Patent Document

Patent Document 1: WO 2016/136448 A

### SUMMARY OF THE INVENTION

### Problems to be Solved by the Invention

In the above related art, the ADC is arranged for each pixel, and thus a speed of analog to digital (AD) conversion can be increased, as compared with a case where the ADC is arranged for each column. However, in the above solid-state imaging element, the repeater transfers digital signals to be processed to the signal processing unit in the unit of rows, and thus an amount of data to be transferred to the signal processing unit increases as the number of pixels (i.e., the number of columns) in a row increases. This causes a problem that a throughput of the signal processing unit increases as the number of columns increases, which decreases a processing speed.

The present technology has been made in view of such a circumstance, and an object thereof is to improve a processing speed in a solid-state imaging element that performs signal processing on a part of image data.

### Solutions to Problems

The present technology has been made to solve the above problems, and a first aspect of the present technology is a solid-state imaging element and a control method thereof, the solid-state imaging element including: a repeater that is connected to a cluster in which a predetermined number of pixels are arrayed and transfers digital signals indicating a time within a predetermined period; a vertical drive circuit that supplies an output timing signal indicating an output timing of each of the predetermined number of pixels and an output enable signal indicating whether or not output of the digital signal is enabled for each of the pixels; a comparator that compares an analog signal corresponding to an amount of exposure with a reference signal varying during the predetermined period and outputs a comparison result; a latch circuit that acquires the digital signal from the repeater and holds the digital signal; a latch control circuit that controls the latch circuit to cause the latch circuit to hold the digital signal when the comparison result is inverted and controls the latch circuit to cause the latch circuit to output the digital signal to the repeater at the timing indicated by the output timing signal; and an enable control unit that supplies the output timing signal to the latch control circuit in a case where the output of the digital signal is set to be enabled in response to the output enable signal. Therefore, output of digital signals can be set to be enabled in the unit of pixels.

Further, in the first aspect, the repeater and the predetermined number of pixels may be arranged in each of a plurality of clusters, and the comparator, the latch circuit, the latch control circuit, and the enable control unit may be arranged in each of the predetermined number of pixels. Therefore, the pixels in the cluster can be sequentially driven.

Further, in the first aspect, a signal processing unit that performs predetermined signal processing on the digital signals transferred by the repeater may be further included. Therefore, the signal processing can be performed on the digital signals output in the unit of pixels.

Further, in the first aspect, the signal processing unit may include first and second signal processing units, the first signal processing unit may perform the signal processing on the digital signals output from a part of the plurality of clusters, and the second signal processing unit may perform the signal processing on the digital signals output from the rest of the plurality of clusters. Therefore, the digital signals can be processed in parallel by the first and second signal processing units.

Further, in the first aspect, the signal processing unit may include a signal processing circuit that performs predetermined signal processing on the output digital signals to generate image data, and a region-of-interest setting unit that sets, as a region of interest, a region of the image data to which the digital signals are to be output. Therefore, the signal processing can be performed on the region of interest.

Further, in the first aspect, the signal processing unit may further include a motion vector detection unit that detects, for each subject in the image data, a motion vector indicating a moving direction of the subject, and a region-of-interest prediction unit that predicts a position of the region of interest in image data to be generated next on the basis of the motion vector. Therefore, the position of the region of interest can be predicted in accordance with the motion.

Further, a second aspect of the present technology is an imaging apparatus including: a repeater that is connected to a cluster in which a predetermined number of pixels are arrayed and transfers digital signals indicating a time within a predetermined period; a vertical drive circuit that supplies an output timing signal indicating an output timing of each of the predetermined number of pixels and an output enable signal indicating whether or not output of the digital signal is enabled for each of the pixels; a comparator that compares an analog signal corresponding to an amount of exposure with a reference signal varying during the predetermined period and outputs a comparison result; a latch circuit that acquires the digital signal from the repeater and holds the digital signal; a latch control circuit that controls the latch circuit to cause the latch circuit to hold the digital signal when the comparison result is inverted and controls the latch circuit to cause the latch circuit to output the digital signal to the repeater at the timing indicated by the output timing signal; an enable control unit that supplies the output timing signal to the latch control circuit in a case where the output of the digital signal is set to be enabled in response to the output enable signal; and a storage unit that stores image data in which the digital signals are arrayed. Therefore, the digital signals output in the unit of pixels can be stored.

### BRIEF DESCRIPTION OF DRAWINGS

FIG. 1 is a block diagram showing a configuration example of an imaging apparatus in a first embodiment of the present technology.

FIG. 2 shows an example of a layered structure of a solid-state imaging element in the first embodiment of the present technology.

FIG. 3 is a block diagram showing a configuration example of the solid-state imaging element in the first embodiment of the present technology.

FIG. 4 is a plan view showing a configuration example of a pixel array unit in the first embodiment of the present technology.

FIG. 5 is a block diagram showing a configuration example of a pixel in the first embodiment of the present technology.

FIG. 6 is a circuit diagram showing a configuration example of a pixel circuit, a differential input circuit, a positive feedback circuit, and an inverter circuit in the first embodiment of the present technology.

FIG. 7 is a block diagram showing a configuration example of a latch unit in the first embodiment of the present technology.

FIG. 8 is a circuit diagram showing a configuration example of a latch control circuit and latch circuits in the first embodiment of the present technology.

FIG. 9 shows a summary of operations of the latch circuit in the first embodiment of the present technology.

FIG. 10 shows a configuration example of repeater units and clusters in the first embodiment of the present technology.

FIG. 11 is a circuit diagram showing a configuration example of a repeater in the first embodiment of the present technology.

FIG. 12 is a block diagram showing a configuration example of a signal processing unit in the first embodiment of the present technology.

FIG. 13 is a timing chart showing an example of an operation for converting a P phase in the first embodiment of the present technology.

FIG. 14 is a timing chart showing an example of an operation for converting a D phase in the first embodiment of the present technology.

FIG. 15 is a timing chart showing an example of an operation in which a zeroth cluster in a 001st column outputs digital signals in the first embodiment of the present technology.

FIG. 16 is a timing chart showing an example of an operation in which a first cluster in the 001st column outputs digital signals in the first embodiment of the present technology.

FIG. 17 is an explanatory diagram showing analog to digital conversion in the first embodiment of the present technology.

FIG. 18 is an explanatory diagram showing an operation of a pixel in which an output enable signal is set to be enabled in the first embodiment of the present technology.

FIG. 19 is an explanatory diagram showing an operation of a pixel in which an output enable signal is set to be disabled in the first embodiment of the present technology.

FIG. 20 illustrates an example of image data before and after a region of interest (ROI) is set in the first embodiment of the present technology.

FIG. 21 illustrates an example of the ROI in the first embodiment of the present technology.

FIG. 22 illustrates image data in which an ROI is set and image data transferred to a signal processing unit in a comparative example.

FIG. 23 illustrates an example of the ROI in the comparative example.

FIG. 24 is a flowchart showing an example of an operation of the solid-state imaging element in the first embodiment of the present technology.

FIG. 25 is a block diagram showing a configuration example of a solid-state imaging element in a second embodiment of the present technology.

FIG. 26 is a plan view showing a configuration example of a pixel array unit in the second embodiment of the present technology.

FIG. 27 is a block diagram showing an example of a schematic configuration of a vehicle control system.

FIG. 28 is an explanatory diagram showing an example of installation positions of a vehicle outside information detection unit and an imaging unit.

### MODE FOR CARRYING OUT THE INVENTION

Hereinafter, modes for carrying out the present technology (hereinafter, referred to as “embodiments”) will be described. Description will be made in the following order.

1. First embodiment (an example where output of digital signals is set to be enabled in the unit of pixels)

2. Second embodiment (an example where output of digital signals is set to be enabled in the unit of pixels and a plurality of signal processing units is provided)

3. Examples of application to moving objects

### 1. First Embodiment

[Configuration Example of Imaging Apparatus]

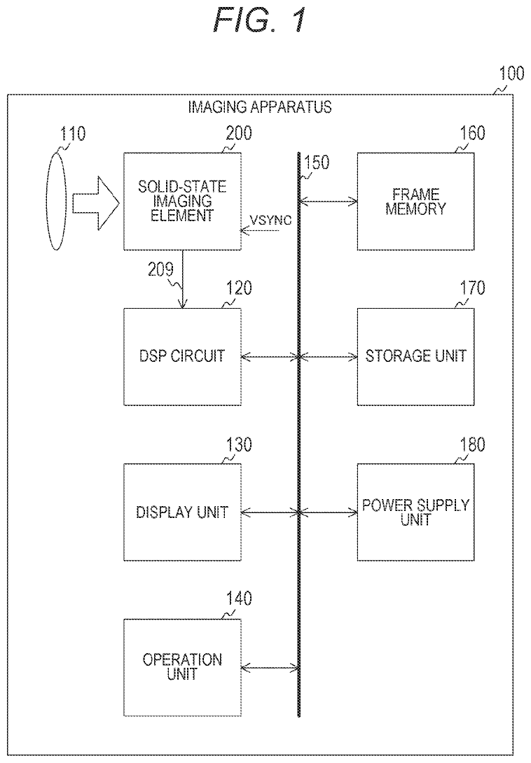

FIG. 1 is a block diagram showing a configuration example of an imaging apparatus 100 in a first embodiment of the present technology. The imaging apparatus 100 is an apparatus for capturing image data and includes an optical unit 110, a solid-state imaging element 200, and a digital signal processing (DSP) circuit 120. The imaging apparatus 100 further includes a display unit 130, an operation unit 140, a bus 150, a frame memory 160, a storage unit 170, and a power supply unit 180. The imaging apparatus 100 is, for example, not only a digital camera such as a digital still camera but also a smartphone, a personal computer, an in-vehicle camera, or the like having an imaging function.

The optical unit 110 collects light from a subject and guides the light to the solid-state imaging element 200. The solid-state imaging element 200 generates image data by photoelectric conversion in synchronization with a vertical synchronization signal VSYNC. Herein, the vertical synchronization signal VSYNC is a periodic signal having a predetermined frequency indicating a timing of capturing an image. The solid-state imaging element 200 supplies the generated image data to the DSP circuit 120 via a signal line 209.

The DSP circuit 120 executes predetermined signal processing with respect to the image data supplied from the solid-state imaging element 200. The DSP circuit 120 outputs the processed image data to the frame memory 160 and the like via the bus 150.

The display unit 130 displays the image data. The display unit 130 is, for example, a liquid crystal panel or an organic electro luminescence (EL) panel. The operation unit 140 generates an operation signal in response to a user operation.

The bus 150 is a common path through which the optical unit 110, the solid-state imaging element 200, the DSP circuit 120, the display unit 130, the operation unit 140, the frame memory 160, the storage unit 170, and the power supply unit 180 exchange data with each other.

The frame memory 160 holds the image data. The storage unit 170 stores various kinds of data such as the image data. The power supply unit 180 supplies power to the solid-state imaging element 200, the DSP circuit 120, the display unit 130, and the like.

[Configuration Example of Solid-State Imaging Element]

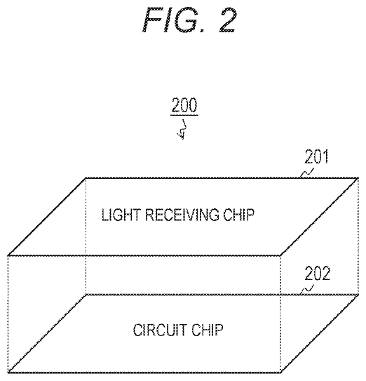

FIG. 2 shows an example of a layered structure of the solid-state imaging element 200 in the first embodiment of the present technology. The solid-state imaging element 200 includes a circuit chip 202 and a light receiving chip 201 layered on the circuit chip 202. Those chips are electrically connected via a connection portion such as a via. Note that the chips can be connected not only by the via but also by Cu—Cu bonding or a bump.

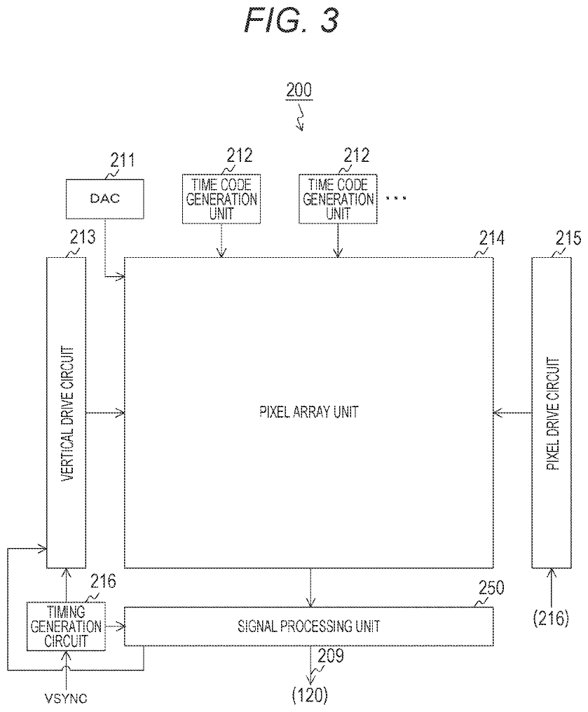

FIG. 3 is a block diagram showing a configuration example of the solid-state imaging element 200 in the first embodiment of the present technology. The solid-state imaging element 200 includes a digital to analog converter (DAC) 211, time code generation units 212, a vertical drive circuit 213, a pixel array unit 214, a pixel drive circuit 215, a timing generation circuit 216, and a signal processing unit 250.

The DAC 211 generates an analog reference signal that varies during a predetermined AD conversion period by digital to analog (DA) conversion. For example, a sawtooth ramp signal is used as the reference signal. The DAC 211 supplies the reference signal to the pixel array unit 214.

Each of the time code generation units 212 generates a digital signal indicating a time within the AD conversion period as a time code. The time code generation unit 212 is realized by, for example, a counter. The counter is, for example, a gray code counter. The time code generation unit 212 supplies the time code to the pixel array unit 214.

In the pixel array unit 214, a plurality of pixels is arrayed in a two-dimensional lattice. Each of the pixels generates an analog signal corresponding to an amount of exposure and converts the analog signal into a digital signal. Then, the pixel supplies the digital signal to the signal processing unit 250 as pixel data.

The vertical drive circuit 213 drives the pixels to cause the pixels to execute AD conversion. The pixel drive circuit 215 drives the pixels to cause the pixels to generate analog signals.

The timing generation circuit 216 controls operation timings of the vertical drive circuit 213, the pixel drive circuit 215, and the signal processing unit 250 in synchronization with a vertical synchronization signal VSYNC.

The signal processing unit 250 performs predetermined signal processing on the pixel data supplied from the pixel array unit 214. As the signal processing, for example, correlated double sampling (CDS) processing and image recognition processing are executed. The signal processing unit 250 supplies the processed data to the DSP circuit 120. Further, the signal processing unit 250 sets an ROI in response to a user operation and supplies setting information regarding the ROI to the vertical drive circuit 213.

[Configuration Example of Pixel Array Unit]

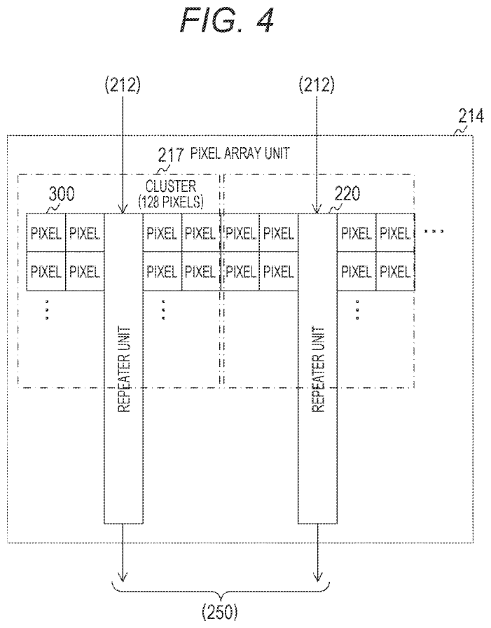

FIG. 4 is a plan view showing a configuration example of the pixel array unit 214 in the first embodiment of the present technology. In the pixel array unit 214, a plurality of pixels 300 and a plurality of repeater units 220 are arranged.

Further, the pixel array unit 214 is divided into a plurality of clusters 217 each including a predetermined number (e.g., 128) of pixels. Further, the repeater unit 220 is provided for each column of the clusters 217. The time code generation unit 212 is also provided for each column of the clusters 217.

The repeater unit 220 transfers a time code. The repeater unit 220 transfers the time code from the corresponding time code generation unit 212 to the pixels 300 in the corresponding clusters 217. Further, the repeater unit 220 transfers pixel data from the pixels 300 in the corresponding clusters 217 to the signal processing unit 250.

[Configuration Example of Pixel]

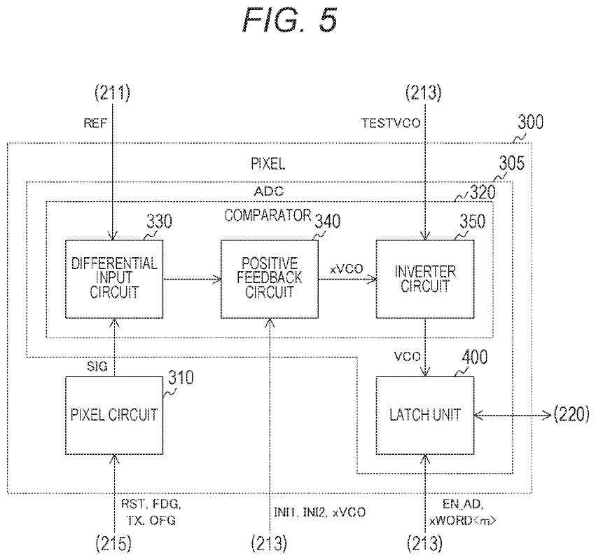

FIG. 5 is a block diagram showing a configuration example of the pixel 300 in the first embodiment of the present technology. The pixel 300 includes a pixel circuit 310 and an ADC 305.

The pixel circuit 310 generates an analog signal corresponding to an amount of exposure as a pixel signal SIG under the control of the pixel drive circuit 215. The pixel circuit 310 supplies the generated pixel signal SIG to the ADC 305.

The ADC 305 performs AD conversion on the analog pixel signal SIG. The ADC 305 includes a comparator 320 and a latch unit 400.

The comparator 320 compares the pixel signal SIG supplied from the pixel circuit 310 with a reference signal REF supplied from the DAC 211. The comparator 320 supplies a comparison result VCO to the latch unit 400. Further, the comparator 320 includes a differential input circuit 330, a positive feedback circuit 340, and an inverter circuit 350.

The differential input circuit 330 amplifies a difference between the pixel signal SIG and the reference signal REF. The positive feedback circuit 340 adds a part of output to input. The inverter circuit 350 inverts output of the positive feedback circuit 340.

The latch unit 400 acquires, from the repeater unit 220, a time code when the comparison result VCO is inverted and holds the time code. Further, the latch unit 400 outputs the held time code as pixel data to the repeater unit 220 under the control of the vertical drive circuit 213.

[Configuration Example of Pixel Circuit and Comparator]

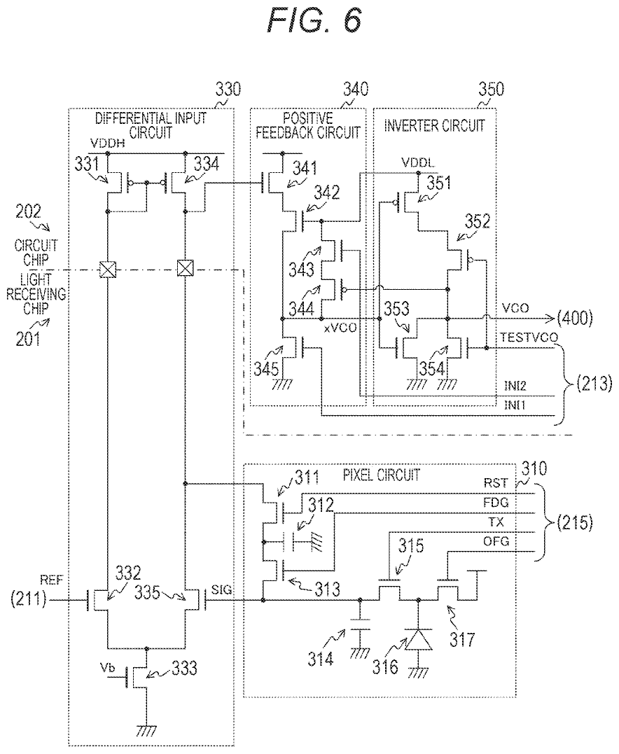

FIG. 6 is a circuit diagram showing a configuration example of the pixel circuit 310, the differential input circuit 330, the positive feedback circuit 340, and the inverter circuit 350 in the first embodiment of the present technology.

The pixel circuit 310 includes a reset transistor 311, a floating diffusion layer 312, an FDG transistor 313, a floating diffusion layer 314, a transfer transistor 315, a photoelectric conversion element 316, and a charge discharging transistor 317. The reset transistor 311, the FDG transistor 313, the transfer transistor 315, and the charge discharging transistor 317 are, for example, n-channel metal oxide semiconductor (nMOS) transistors.

The differential input circuit 330 includes p-channel MOS (pMOS) transistors 331 and 334, differential transistors 332 and 335, and a current source transistor 333.

Further, the positive feedback circuit 340 includes nMOS transistors 341, 342, 343, and 345 and a pMOS transistor 344. The inverter circuit 350 includes pMOS transistors 351 and 352 and nMOS transistors 353 and 354.

The reset transistor 311 in the pixel circuit 310 initializes the floating diffusion layers 312 and 314 in response to a reset signal RST supplied from the pixel drive circuit 215.

The floating diffusion layers 312 and 314 store charges and generate a voltage corresponding to a charge amount.

The FDG transistor 313 opens and closes a path between the floating diffusion layers 312 and 314 in response to a control signal FDG supplied from the pixel drive circuit 215, thereby controlling charge-voltage conversion efficiency.

The transfer transistor 315 transfers a charge from the photoelectric conversion element 316 to the floating diffusion layer 314 in response to a transfer signal TX supplied from the pixel drive circuit 215. The photoelectric conversion element 316 generates a charge by photoelectric conversion. The photoelectric conversion element 316, for example, is a photodiode.

The charge discharging transistor 317 discharges the charge from the photoelectric conversion element 316 in response to a control signal OFG supplied from the pixel drive circuit 215, thereby initializing a charge amount thereof.

The pMOS transistors 331 and 334 in the differential input circuit 330 are connected in parallel to a power supply voltage VDDH. A gate of the pMOS transistor 331 is connected to its own drain and a gate of the pMOS transistor 334. Further, a drain of the pMOS transistor 334 is connected to a gate of the nMOS transistor 341 in the positive feedback circuit 340.

The differential transistor 332 is inserted between the pMOS transistor 331 and the current source transistor 333. Further, a reference signal REF is input to a gate of the differential transistor 332. The differential transistor 335 is inserted between the pMOS transistor 334 and the current source transistor 333. Further, a pixel signal SIG is input to a gate of the differential transistor 335. The current source transistor 333 is inserted between the differential transistors 332 and 335 and a ground terminal. A constant bias voltage Vb is applied to a gate of the current source transistor 333.

Further, the pixel circuit 310, the differential transistors 332 and 335, and the current source transistor 333 are arranged on the light receiving chip 201. Similarly, the DAC 211 and the pixel drive circuit 215 are also arranged on the light receiving chip 201. Meanwhile, the pMOS transistors 331 and 334, the positive feedback circuit 340, and the inverter circuit 350 are arranged on the circuit chip 202. The time code generation unit 212, the vertical drive circuit 213, the latch unit 400, the repeater unit 220, and the signal processing unit 250 are also arranged on the circuit chip 202.

Note that circuits arranged on the light receiving chip 201 and the circuit chip 202 are not limited to those shown in FIG. 6.

The nMOS transistors 341, 342, and 345 in the positive feedback circuit 340 are connected in series between a power supply terminal and a ground terminal. Further, a gate of the nMOS transistor 342 is connected to a power supply voltage VDDL lower than the power supply voltage VDDH.

The nMOS transistor 343 and the pMOS transistor 344 are connected in series between the gate of the nMOS transistor 342 and a connection node between the nMOS transistors 342 and 345. Further, a potential of the connection node is supplied to the inverter circuit 350 as an inverted signal xVCO.

Further, a drive signal INI1 supplied from the vertical drive circuit 213 is input to a gate of the nMOS transistor 345. A drive signal INI2 supplied from the vertical drive circuit 213 is input to a gate of the nMOS transistor 343.

The pMOS transistors 351 and 352 in the inverter circuit 350 are connected in series to the power supply voltage VDDL. The nMOS transistors 353 and 354 are connected in parallel between the pMOS transistors 352 and ground terminals.

Further, a drive signal TESTVCO supplied from the vertical drive circuit 213 is input to each gate of the pMOS transistor 352 and the nMOS transistor 354. A gate of the pMOS transistor 344 is connected to a connection node between the pMOS transistor 352 and the nMOS transistor 354, and a potential of the connection node is supplied to the latch unit 400 as the comparison result VCO.

Note that the pixel circuit 310, the differential input circuit 330, the positive feedback circuit 340, and the inverter circuit 350 each are not limited to the circuit configurations shown in FIG. 6 as long as those circuits can realize the function described with reference to FIG. 5.

[Configuration Example of Latch Unit]

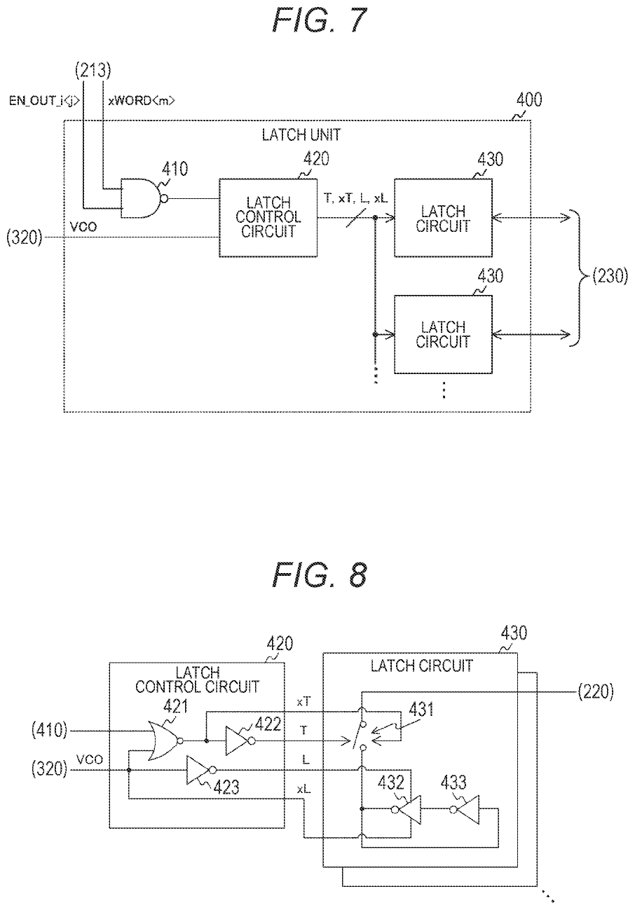

FIG. 7 is a block diagram showing a configuration example of the latch unit 400 in the first embodiment of the present technology. The latch unit 400 includes a Not-AND (NAND) gate 410, a latch control circuit 420, and a plurality of latch circuits 430.

The NAND gate 410 outputs Not-AND of an output enable signal EN_OUT_i<j> and an output timing signal xWORD<m> to the latch control circuit 420. The output timing signal xWORD<m> is a signal obtained by inverting an output timing signal WORD<m> indicating an output timing of the m-th (m is an integer) pixel among the pixels in the cluster 217. In a case where the number of pixels in the cluster 217 is “128”, “0” to “127” are set to m. Output timing signals xWORD<0> to xWORD<127> are supplied to all the clusters.

Further, the output enable signal EN_OUT_i<j> is a signal indicating whether or not output of pixel data of the corresponding pixel is enabled. The vertical drive circuit 213 outputs the output enable signal EN_OUT_i<j> having a value of “1” in a case where the output is set to be enabled, and outputs the output enable signal EN_OUT_i<j> having a value of “0” in a case where the output is set to be disabled.

The character i denotes a three-digit integer indicating a column of the clusters 217. In a case where the number of columns of the clusters 217 is, for example, “512”, values of “000” to “511” are set to i. Further, the character j denotes an integer indicating a pixel in the corresponding column. For example, in a case where 3584 pixels are included in the column of the clusters 217, values of “0” to “3583” are set to j. For example, an output enable signal EN_OUT_000<0> is input to the zeroth pixel in the 000th column.

In a case where the number of columns of the clusters 217 is “512” and the number of pixels in each column is “3584”, the total number of pixels is 512×3584. The output enable signal EN_OUT_i<j> is individually set for each of those pixels. The output enable signals EN_OUT_i<j> for all the pixels are set to be enabled in an initial state.

The latch control circuit 420 controls each latch circuit 430 to cause the latch circuit 430 to hold a time code when the comparison result VCO supplied from the comparator 320 is inverted. Further, the latch control circuit 420 controls the latch circuit 430 in response to a signal supplied from the NAND gate 410 and causes the latch circuit 430 to output the held time code as pixel data.

The latch circuit 430 holds the time code supplied from the repeater 230 in accordance with the latch control circuit 420 and outputs the time code to the repeater 230 as the pixel data. The latch circuits 430 are provided corresponding to a bit length of the time code.

FIG. 8 is a circuit diagram showing a configuration example of the latch control circuit 420 and the latch circuits 430 in the first embodiment of the present technology.

The latch control circuit 420 includes a Not-OR (NOR) gate 421 and inverters 422 and 423. Each of the latch circuits 430 includes a switch 431 and inverters 432 and 433.

The NOR gate 421 outputs Not-OR of a signal supplied from the NAND gate 410 and the comparison result VCO supplied from the comparator 320. The Not-OR is supplied to the inverter 422 and the switch 431 as a control signal xT. The inverter 422 inverts the control signal xT and supplies the inverted control signal to the switch 431 as a control signal T. The inverter 423 inverts the comparison result VCO and supplies the inverted comparison result VCO to the inverter 432 as a control signal L. Further, the comparison result VCO is supplied to the inverter 432 as a control signal xL.

In each latch circuit 430, the inverter 432 outputs an inverted value of output of the inverter 433 to the switch 431 and an input terminal of the inverter 433 in response to the control signals L and xL. The inverter 432 outputs the inverted value in a case where the control signal L is at a high level and the control signal xL is at a low level and does not output the inverted value in other cases. The inverter 433 outputs an inverted value of the output of the inverter 432 to an input terminal of the inverter 432.

The switch 431 opens and closes a path between the repeater unit 220 and an output terminal of the inverter 432 in response to the control signals T and xT. The inverter 432 transitions to a closed state in a case where the control signal T is at a high level and the control signal xT is at a low level and transitions to an open state in other cases.

With the configurations shown in FIGS. 7 and 8, the latch control circuit 420 controls the latch circuit 430 to cause the latch circuit 430 to hold a digital time code when the comparison result VCO is inverted. Thus, an analog pixel signal SIG is AD converted into a digital time code. Further, in a case where the corresponding output timing signal WORD<m> and output enable signal EN_OUT_i<j> are “1”, the latch control circuit 420 controls the latch circuit 430 to cause the latch circuit 430 to output the held time code as pixel data. Note that the circuit configuration of the latch unit 400 is not limited to the configurations shown in FIGS. 7 and 8 as long as the latch unit 400 can realize the functions described with reference to FIGS. 7 and 8.

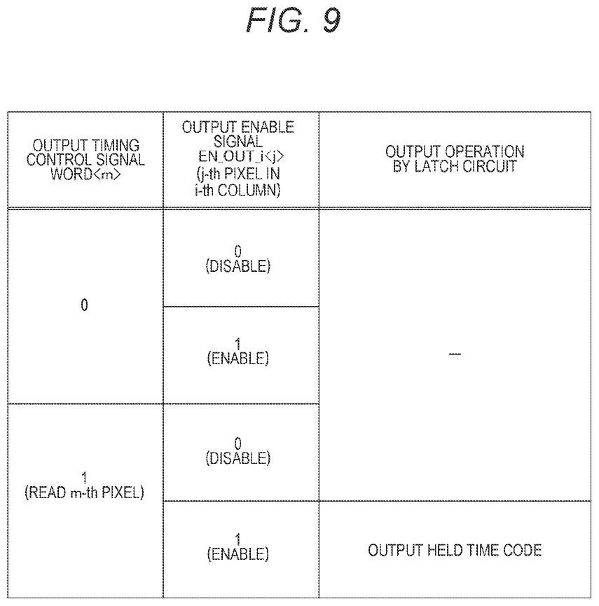

FIG. 9 shows a summary of operations of the latch circuit 430 in the first embodiment of the present technology. In a case where the output timing signal WORD<m> is “1” and the output enable signal EN_OUT_i<j> is “1” (enabled), the corresponding latch circuit 430 outputs the held time code as the pixel data. Meanwhile, in a case where the output timing signal WORD<m> is “0” or the output enable signal EN_OUT_i<j> is “0” (disabled), the pixel data is not output.

[Configuration Example of Repeater Unit]

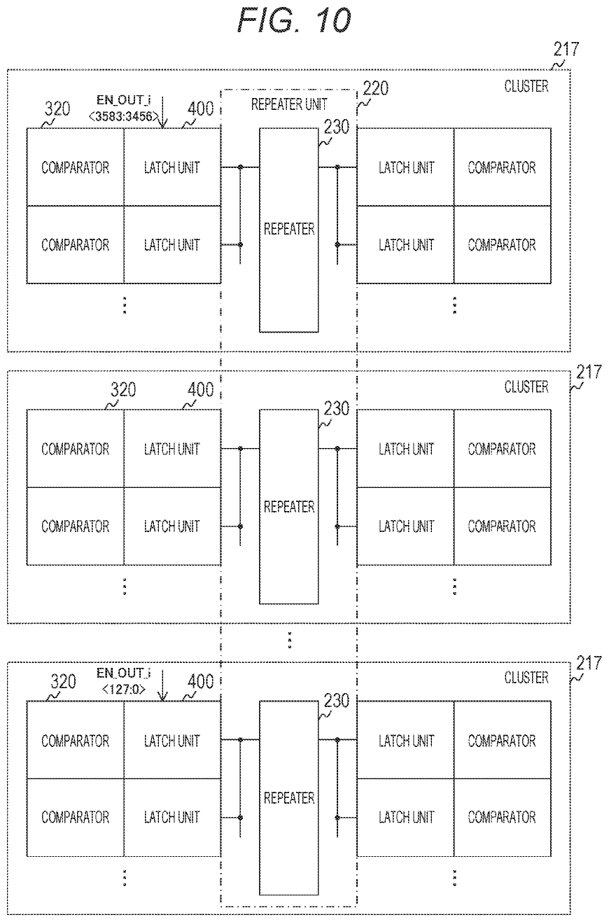

FIG. 10 shows a configuration example of the repeater units 220 and the clusters 217 in the first embodiment of the present technology. In each of the repeater units 220, a plurality of repeaters 230 is vertically arrayed. The clusters 217 and the repeaters 230 are connected on a one-to-one basis. For example, in a case where 28 clusters 217 are vertically arrayed in each column, 28 repeaters 230 are arrayed.

Each of the repeaters 230 transfers time data. The repeater 230 is, for example, a shift register. Each repeater 230 is connected to all the latch units 400 in the corresponding cluster 217 via a local bit line.

The repeater 230 transfers a time code to the corresponding latch units 400. Further, the repeater 230 transfers pixel data from the corresponding latch units 400 to the signal processing unit 250.

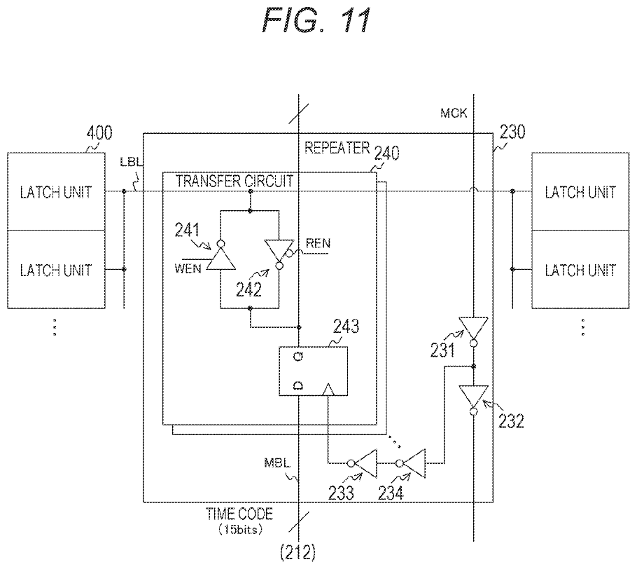

FIG. 11 is a circuit diagram showing a configuration example of the repeater 230 in the first embodiment of the present technology. The repeater 230 includes a plurality of transfer circuits 240 and inverters 231 to 234. The transfer circuits 240 are provided corresponding to a bit length of the time code. Each of the transfer circuits 240 includes inverters 241 and 242 and a flip-flop 243.

The inverter 231 inverts a master clock signal MCK having a predetermined frequency and supplies the inverted master clock signal to the inverters 232 and 234. The inverter 232 inverts the signal supplied from the inverter 231 and supplies the inverted signal to the subsequent repeater 230.

The inverter 234 inverts the signal supplied from the inverter 231 and supplies the inverted signal to the inverter 233. The inverter 233 inverts the signal supplied from the inverter 234 and supplies the inverted signal to each flip-flop 243.

The flip-flop 243 holds a corresponding bit of the time code in synchronization with the signal supplied from the inverter 233. The corresponding bit of the time code supplied from the time code generation unit 212 is input to an input terminal of the flip-flop 243 via a master bit line MBL. Further, the flip-flop 243 supplies the held bit to the inverter 241 and the subsequent repeater 230.

The inverter 241 inverts the bit supplied from the flip-flop 243 in response to a control signal WEN and supplies the inverted bit to each of the corresponding latch units 400 via a local bit line LBL.

The inverter 242 inverts the bits supplied from the corresponding latch units 400 in response to a control signal REN and supplies the inverted bits to the subsequent repeater 230.

[Configuration Example of Signal Processing Unit]

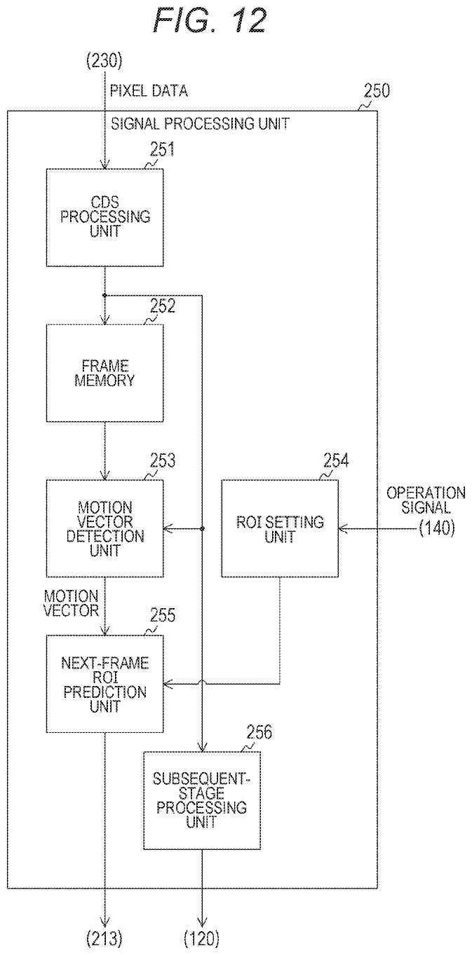

FIG. 12 is a block diagram showing a configuration example of the signal processing unit 250 in the first embodiment of the present technology. The signal processing unit 250 includes a CDS processing unit 251, a frame memory 252, a motion vector detection unit 253, an ROI setting unit 254, a next-frame ROI prediction unit 255, and a subsequent-stage processing unit 256.

The CDS processing unit 251 performs CDS processing on each piece of pixel data supplied from the pixel array unit 214. The CDS processing unit 251 supplies the processed pixel data to the frame memory 252, the motion vector detection unit 253, and the subsequent-stage processing unit 256. The image data (frame) in which the pieces of processed pixel data are arrayed is supplied to the motion vector detection unit 253 as a current frame. Note that the CDS processing unit 251 is an example of a signal processing circuit recited in the claims.

The frame memory 252 holds the image data (frame) in which the pieces of pixel data supplied from the CDS processing unit 251 are arrayed as a past frame.

On the basis of the past frame held by the frame memory 252 and the current frame, the motion vector detection unit 253 detects, for each subject in the frame, a vector indicating a moving direction and a distance of the subject as a motion vector. For example, the motion vector detection unit 253 divides the current frame into a plurality of blocks and performs, on each block, block matching for finding the most matching block from the past frame. Then, the motion vector detection unit 253 detects, as a motion vector, a vector from a block in the past frame to a corresponding block in the current frame. The motion vector detection unit 253 supplies the detected motion vector to the next-frame ROI prediction unit 255.

In response to an operation signal from the operation unit 140, the ROI setting unit 254 sets a partial region in the image data as a region of interest (ROI) to be subjected to predetermined signal processing (e.g., image recognition processing). Herein, a shape of the ROI is not limited, and the ROI setting unit 254 can set a rectangular, circular, or elliptical ROI. The ROI setting unit 254 supplies setting information for specifying an outer periphery of the ROI to the next-frame ROI prediction unit 255. In a case where the ROI is a rectangle, the setting information indicates, for example, coordinates of each of a pair of diagonal corners of the rectangle. Further, in a case where the ROI is a circle, the setting information indicates, for example, center coordinates and a radius of the circle. Note that the ROI setting unit 254 is an example of a region-of-interest setting unit recited in the claims.

The next-frame ROI prediction unit 255 predicts a position of the ROI in the next frame of the current frame. The next-frame ROI prediction unit 255 predicts the position of the ROI in the next frame on the basis of the setting information regarding the ROI in the current frame and the motion vector supplied from the motion vector detection unit 253. For example, the next-frame ROI prediction unit 255 holds the setting information regarding the ROI in the current frame, moves the ROI by an amount of the motion vector, and obtains a position of the moved ROI as the position of the ROI in the next frame. The next-frame ROI prediction unit 255 supplies setting information regarding the predicted ROI to the vertical drive circuit 213. In the first prediction, an ROI set by the ROI setting unit 254 is used as the ROI in the current frame. In the second and subsequent predictions, the ROI in the current frame is updated on the basis of the ROI predicted in the previous time.

The vertical drive circuit 213 performs setting so that output enable signals EN_OUT are enabled for respective pixels in the set ROI and output enable signals EN_OUT are disabled for the other pixels.

The subsequent-stage processing unit 256 performs various kinds of signal processing such as demosaicing and image recognition processing on the frame that has been subjected to the CDS processing. For example, in a case where the ROI is set, the subsequent-stage processing unit 256 executes image recognition processing and the like on the ROI. The subsequent-stage processing unit 256 supplies the processed data to the DSP circuit 120.

Note that part of or the entire processing of the signal processing unit 250 may be performed by a circuit (e.g., the DSP circuit 120) outside the solid-state imaging element 200, instead of the signal processing unit 250.

Further, the signal processing unit 250 detects the motion vector and predicts the ROI in the next frame, but, in a case where the ROI is set in a range in which no motion occurs, the signal processing unit 250 may not include the motion vector detection unit 253 or the next-frame ROI prediction unit 255.

[Operation Example of Solid-State Imaging Element]

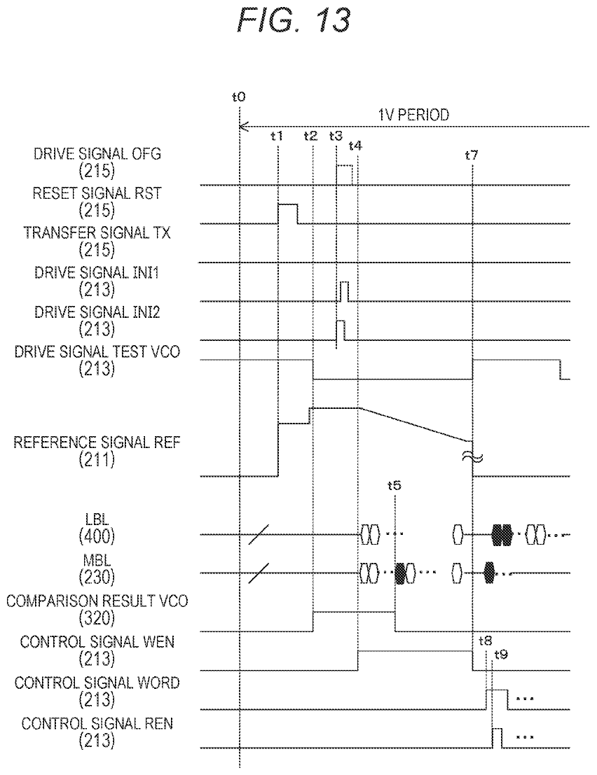

FIG. 13 is a timing chart showing an example of an operation for converting a P phase in the first embodiment of the present technology. Herein, the P phase indicates a level of a pixel signal SIG obtained when the pixel circuit 310 is initialized.

At a timing to, a 1V period starts. Herein, the 1V period is a period until AD conversion of all the pixels is completed. A length of the 1V period is set to, for example, a period of a vertical synchronization signal VSYNC.

At a timing t1 after the timing t0, the pixel drive circuit 215 supplies a reset signal RST to all the pixels to initialize the floating diffusion layers. As a result, the P phase is generated in all the pixels. At a timing t2 after the timing t1, the vertical drive circuit 213 changes a drive signal TESTVCO from a high level to a low level. Further, the comparator 320 starts outputting a high-level comparison result VCO.

At a timing t3 after the timing t2, the vertical drive circuit 213 sequentially supplies drive signals INI2 and INI1 to initialize the positive feedback circuit 340. During a period from a timing t4 to a timing t7 after the timing t3, the vertical drive circuit 213 supplies a control signal WEN, and the DAC 211 changes a reference signal REF in a slope shape. When the P phase exceeds a level of the reference signal REF at t5 within this period, the comparator 320 inverts the comparison result VCO. The repeater unit 220 transfers time data to the pixels in response to the control signal WEN, and the latch unit 400 holds the time data obtained when the comparison result VCO is inverted. Thus, the P phase is AD converted in all the pixels.

Further, at a timing t8 after the timing t7, the vertical drive circuit 213 supplies an output timing signal WORD to the zeroth pixels in the clusters 217 during a certain period. At a timing t9 within a transmission period of the output timing signal WORD, the vertical drive circuit 213 supplies a control signal REN. In response to the control signal REN, the repeater unit 220 transfers the zeroth pixel data (time data) of each cluster to the signal processing unit 250.

Subsequently, the output timing signal WORD is sequentially transmitted to the 1st to 127th pixels in each cluster 217, and the control signal REN is supplied within a transmission period thereof. Thus, pixel data in which the P phase has been converted is transferred from all the pixels to the signal processing unit 250.

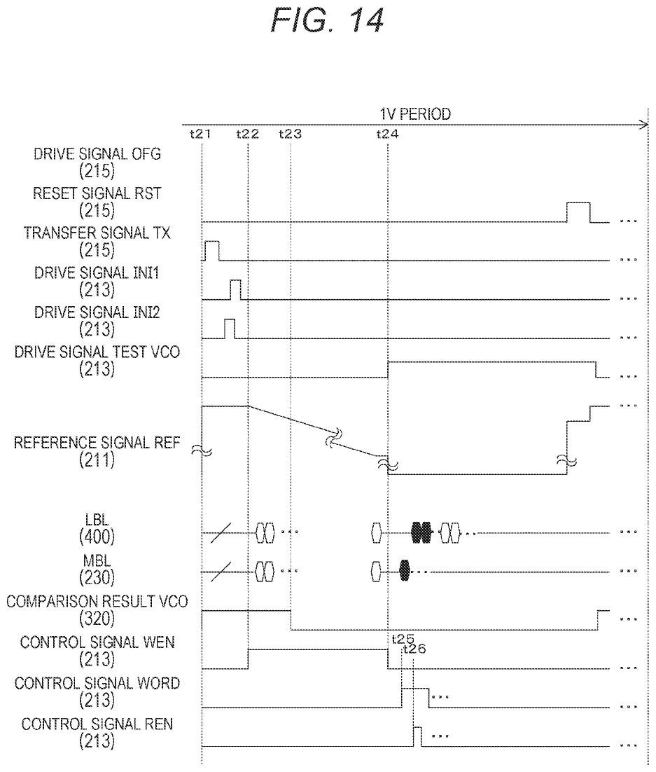

FIG. 14 is a timing chart showing an example of an operation for converting a D phase in the first embodiment of the present technology. Herein, the D phase indicates a level of the pixel signal SIG corresponding to the amount of exposure.

At a timing t21 after the conversion of the P phase, the comparator 320 starts outputting the high-level comparison result VCO, and immediately thereafter, the pixel drive circuit 215 supplies a transfer signal TX. When the transfer signal TX is supplied, exposure of all the pixels ends, and the D phase is generated in all the pixels. Further, immediately after the transfer signal TX is supplied, the vertical drive circuit 213 sequentially supplies the drive signals INI2 and INI1.

During a period from a timing t22 to a timing t24 after the timing t21, the vertical drive circuit 213 supplies the control signal WEN, and the DAC 211 changes the reference signal REF in a slope shape. When the D phase exceeds the level of the reference signal REF at t23 within this period, the comparator 320 inverts the comparison result VCO. The latch unit 400 holds time data obtained when the comparison result VCO is inverted. Thus, the D phase is AD converted in all the pixels.

At a timing t25 after the timing t24, the vertical drive circuit 213 supplies an output timing signal WORD to the zeroth pixels in the clusters 217 during a certain period. At a timing t26 within a transmission period of the output timing signal WORD, the vertical drive circuit 213 supplies a control signal REN. In response to the control signal REN, the repeater unit 220 transfers the zeroth pixel data (time data) of each cluster to the signal processing unit 250.

Subsequently, the output timing signal WORD is sequentially transmitted to the 1st to 127th pixels in each cluster 217, and the control signal REN is supplied within a transmission period thereof. Thus, pixel data in which the D phase has been converted is transferred from all the pixels to the signal processing unit 250.

The subsequent signal processing unit 250 performs CDS processing for obtaining a difference between the P phase and the D phase for all the pixels.

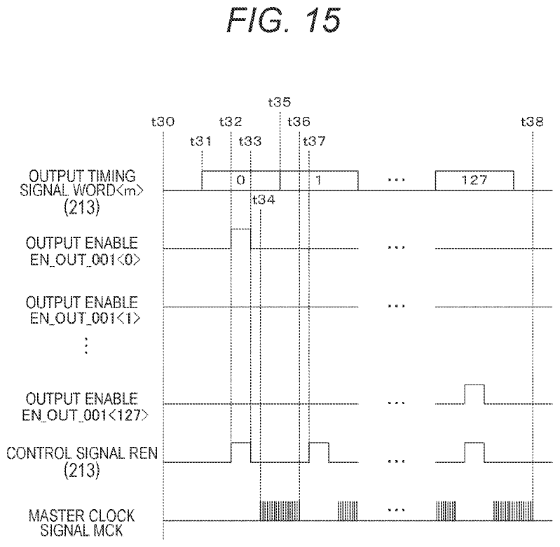

FIG. 15 is a timing chart showing an example of an operation in which a zeroth cluster 217 in a 001st column outputs digital signals in the first embodiment of the present technology.

At a timing t30, supply of the control signal WEN ends, and AD conversion of the P phase is completed in all the pixels. During a period from a timing t31 to a timing t35 after the timing t30, the vertical drive circuit 213 supplies a high-level output timing signal WORD<0> to the zeroth pixel of each cluster. In this period, output timing signals WORD<1> to WORD<127> are set to a low level.

During a pulse period from a timing t32 to a timing t33, the timing t32 being a timing at which a certain delay time has elapsed from the timing t30, the vertical drive circuit 213 supplies a high-level output enable signal EN_OUT_001<0>. Further, during the pulse period, the vertical drive circuit 213 supplies a high-level control signal REN. Because the output timing signal WORD<0> and the output enable signal EN_OUT_001<0> are at a high level, pixel data of the P phase is output from the zeroth pixel in the 001st column.

At a timing t34 at which a clearance period has elapsed from the timing t33, supply of a master clock signal MCK is started. The repeater unit 220 transfers the pixel data of the P phase in synchronization with the master clock signal MCK.

During a certain period from the timing t35, the vertical drive circuit 213 supplies a high-level output timing signal WORD<1> to the first pixel of each cluster. In this period, the output timing signals WORD<m> in which m is not “1” are set to a low level.

At a timing t36 after the timing t35, the supply of the master clock signal MCK is stopped. At a timing t37 at which a clearance period has elapsed from the timing t36, the vertical drive circuit 213 supplies a high-level control signal REN during a pulse period. During this period, the output enable signal EN_OUT_001<1> is set to a low level. Because the output enable signal EN_OUT_001<1> is at a low level (disabled), the pixel data of the P phase is not output from the first pixel in the 001st column.

Subsequently, the output timing signal WORD, the output enable signal EN_OUT, and the control signal REN are sequentially supplied to the 2nd to 127th pixels. Then, at a timing t38, the transfer of the P phase is completed in all the pixels.

After the P phase is transferred, the D phase is sequentially transferred for the 0th to 127th pixels. In FIG. 15, the transfer of the D phase is omitted.

As shown in FIG. 15, the pixel data is output from a pixel (e.g., the zeroth pixel) in which the output enable signal EN_OUT is enabled. Meanwhile, the pixel data is not output from a pixel (e.g., the first pixel) in which the output enable signal EN_OUT is disabled.

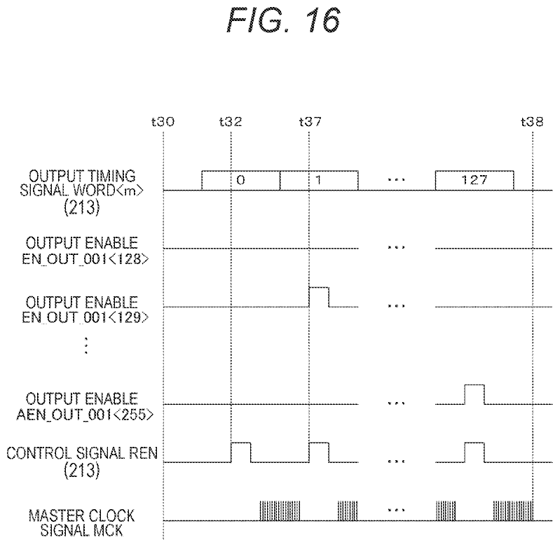

FIG. 16 is a timing chart showing an example of an operation in which the first cluster 217 in the 001st column outputs digital signals in the first embodiment of the present technology.

Output enable signals EN_OUT_001<128> to EN_OUT_001<255> are supplied to the 0th to 127th pixels in the first cluster 217.

At the timing t32, the vertical drive circuit 213 supplies the control signal REN during the pulse period, whereas sets the output enable signal EN_OUT_001<128> to a low level. Thus, the pixel data of the P phase is not output from the 128th pixel in the 001st column (in other words, the zeroth pixel in the first cluster).

Further, at a timing t37, the vertical drive circuit 213 supplies a high-level output enable signal EN_OUT_001<129> and the control signal REN during the pulse period. The pixel data of the P phase is output from the 129th pixel in the 001st column (in other words, the first pixel in the first cluster).

Subsequently, the output timing signal WORD, the output enable signal EN_OUT, and the control signal REN are sequentially supplied to the 2nd to 127th pixels, and the transfer of the P phase is completed in all the pixels at the timing t38.

As shown in FIG. 16, the pixel data is output from a pixel (e.g., the first pixel) in which the output enable signal EN_OUT is enabled. Meanwhile, the pixel data is not output from a pixel (e.g., the zeroth pixel) in which the output enable signal EN_OUT is disabled.

Further, output enable signals EN_OUT_001<256> to EN_OUT_001<383> are supplied to the second cluster 217 in the 001st column. Subsequently, 128-bit output enable signals are similarly supplied to the third and subsequent clusters 217. Output enable signals EN_OUT_001<(k×128> to EN_OUT_001<(k×128+127> are supplied to the k-th (k is an integer) cluster 217. For example, output enable signals EN_OUT_001<3456> to EN_OUT_001<3583> are supplied to the 27th cluster 217. The same applies to columns other than the 001st column.

As shown in FIGS. 15 and 16, the output timing signals WORD<0> to WORD<127> are sequentially supplied to all the clusters. Then, in a case where the corresponding output enable signal EN_OUT_i<j> is enabled, pixel data is output from the corresponding pixel, whereas, in a case where the corresponding output enable signal EN_OUT_i<j> is disabled, the pixel data is not output. As described above, the solid-state imaging element 200 can set whether or not to enable output of digital pixel data in the unit of pixels. Note that, in a case where the output enable signal EN_OUT_i<j> is set to be enabled for all the pixels, pixel data of the m-th pixels in all the clusters is output in response to the output timing signal WORD<m>. Assuming that the total number of pixels is N (N is an integer), the number of clusters is N/128, and therefore N/128 pieces of pixel data are simultaneously output in response to the output timing signal WORD<m>.

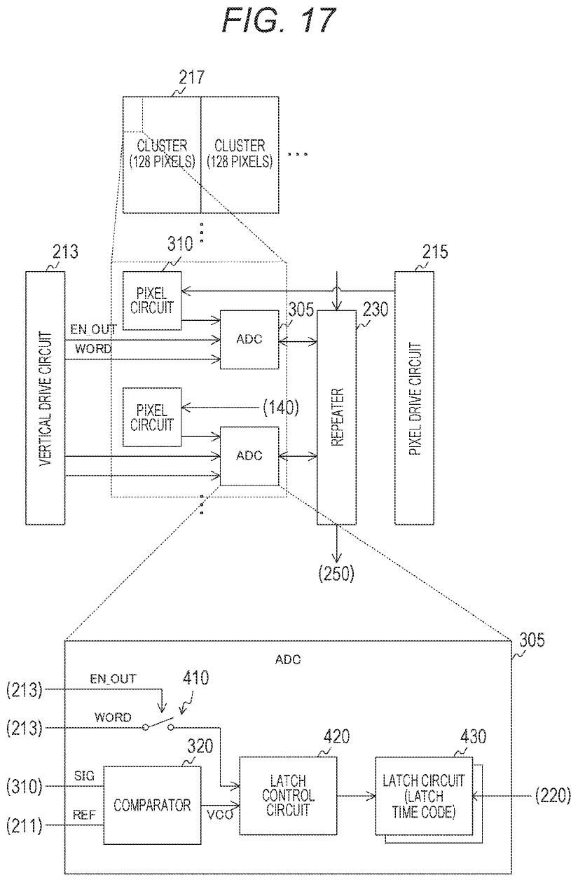

FIG. 17 is an explanatory diagram showing analog to digital conversion in the first embodiment of the present technology. A predetermined number (e.g., 128) of pixels and the repeater 230 are arranged in each of the plurality of clusters 217.

The repeater 230 is connected to the cluster 217 in which the predetermined number (e.g., 128) of pixels are arrayed. The repeater 230 transfers a time code.

The pixel circuit 310 and the ADC 305 are arranged in each pixel. The NAND gate 410, the comparator 320, the latch control circuit 420, and the latch circuits 430 are arranged in the ADC 305.

Note that, in FIG. 17, the NAND gate 410 is represented by a switch symbol for convenience of description. Further, xWORD obtained by inverting an output timing signal WORD signal is input to the NAND gate 410, but, for convenience of description, FIG. 17 shows that the signal that has not been inverted is input.

The pixel drive circuit 215 drives the pixel circuits 310 of all the pixels to cause the pixel circuits 310 to generate analog pixel signals SIG corresponding to the amount of exposure.

The comparator 320 compares the pixel signal SIG with a reference signal REF varying during a predetermined AD conversion period and outputs a comparison result VCO. When the comparison result is inverted, the latch control circuit 420 controls each of the latch circuits 430 to cause the latch circuit 430 to hold (in other words, latch) a digital time code indicating a time within the AD conversion period. The latch circuit 430 acquires the time code from the repeater 230 and latches the time code under the control of the latch control circuit 420. With the above control, the analog pixel signal SIG is converted into the digital time code in all the pixels.

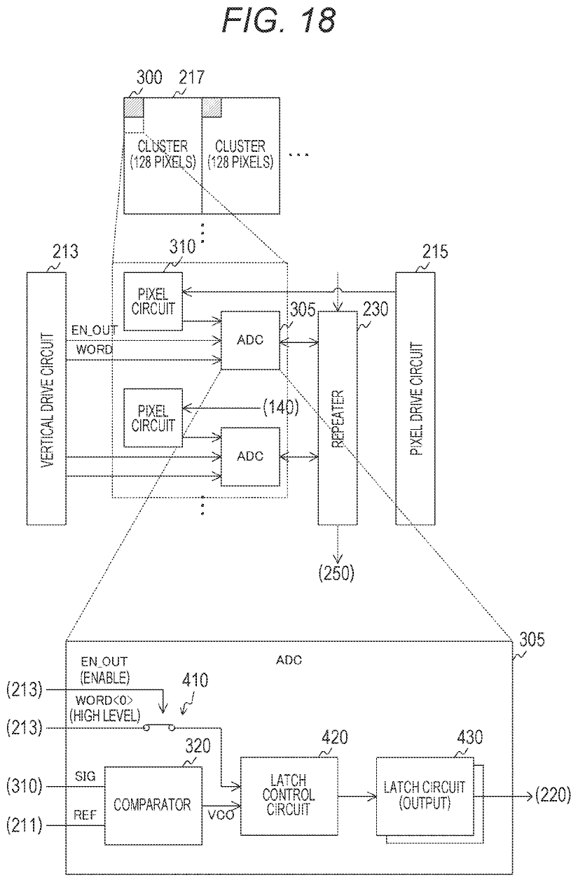

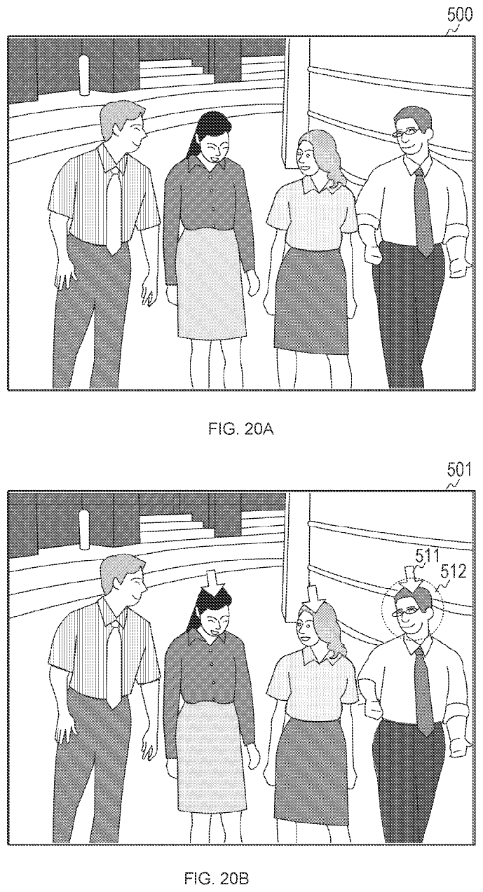

FIG. 18 is an explanatory diagram showing an operation of a pixel in which an output enable signal EN_OUT is set to be enabled in the first embodiment of the present technology.

The vertical drive circuit 213 supplies an output enable signal EN_OUT to the NAND gates 410. Further, the vertical drive circuit 213 sequentially drives 128 pixels in response to output timing signals WORD<0> to WORD<127> to cause the pixels to output pixel data.

Herein, it is assumed that output of certain pixel data in the ROI is set to be enabled in response to the output enable signal EN_OUT. In this case, the NAND gate 410 supplies the corresponding output timing signal WORD<0> to the latch control circuit 420. The latch control circuit 420 controls each latch circuit 430 to cause the latch circuit 430 to output a digital time code as the pixel data to the repeater 230 at a timing indicated by the output timing signal WORD<0>. The repeater 230 transfers the pixel data to the signal processing unit 250. The signal processing unit 250 performs signal processing such as image recognition processing on the transferred pixel data.

Note that the NAND gate 410 is an example of an enable control unit recited in the claims.

FIG. 19 is an explanatory diagram showing an operation of a pixel in which an output enable signal EN_OUT is set to be disabled in the first embodiment of the present technology.

Herein, it is assumed that output of certain pixel data outside the ROI is set to be disabled in response to the output enable signal EN_OUT. In this case, the NAND gate 410 does not supply the corresponding output timing signal WORD<1> to the latch control circuit 420. Because the output timing signal WORD<1> is not supplied, the latch control circuit 420 does not cause each latch circuit 430 to output pixel data.

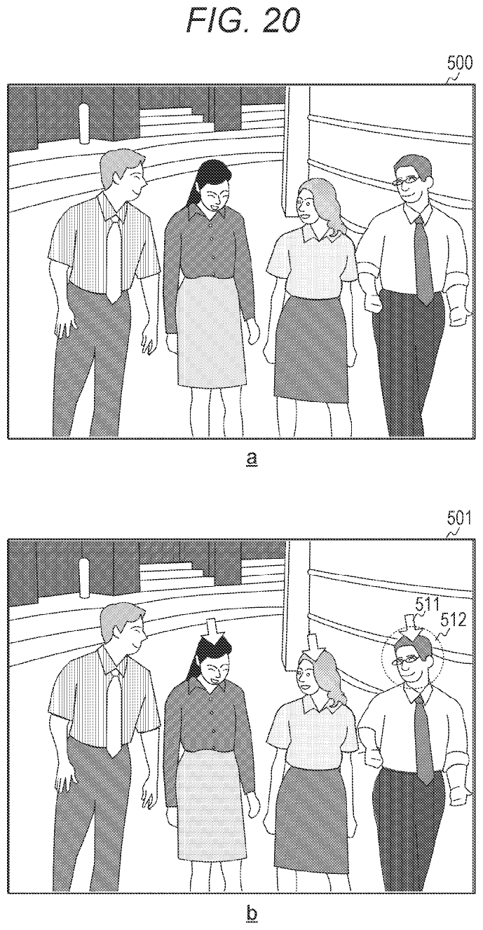

As shown in FIGS. 19 and 20, the solid-state imaging element 200 can set whether or not to output pixel data to the repeater 230 in the unit of pixels in response to the output enable signal EN_OUT.

FIG. 20 illustrates an example of image data before and after the ROI is set in the first embodiment of the present technology. In FIG. 20, a illustrates an example of image data before the ROI is set. In FIG. 20, b illustrates an example of image data after the ROI is set.

In a case where the ROI is not set, the solid-state imaging element 200 continuously captures image data in synchronization with a vertical synchronization signal VSYNC, and the display unit 130 displays image data 500 as illustrated in a of FIG. 20.

A user refers to the displayed image data and sets the ROI by operating a touchscreen or the like. For example, a circular ROI 512 is set as illustrated in b of FIG. 20.

The motion vector detection unit 253 performs block matching or the like to detect a motion vector 511 on the basis of the past image data (frame) 500 and current image data (frame) 501.

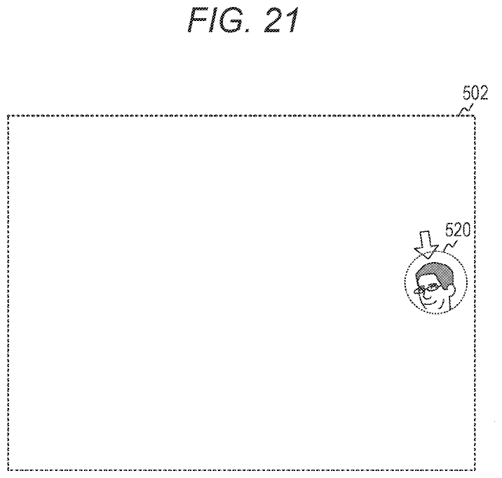

FIG. 21 illustrates an example of the ROI in the first embodiment of the present technology. In b of FIG. 21, a dotted line indicates an outer periphery of the image data before the ROI is set. When the motion vector 511 of the ROI is detected, the next-frame ROI prediction unit 255 predicts a position of the ROI in next image data 502 of the current image data on the basis of the motion vector 511. Then, the next-frame ROI prediction unit 255 supplies setting information regarding the predicted ROI to the vertical drive circuit 213.

The vertical drive circuit 213 performs setting to enable output enable signals EN_OUT for pixels in the predicted ROI and disable output enable signals EN_OUT for pixels outside the ROI. Thus, as illustrated in FIG. 21, only pixel data in an ROI 520 in the next image data 502 is output to the repeater 230 and is transferred to the signal processing unit 250. Therefore, the ROI 520 is subjected to signal processing (e.g., CDS processing and image recognition processing), and the processed ROI 520 is displayed.

As illustrated in FIGS. 20 and 21, the solid-state imaging element 200 predicts the ROI of the next frame, and therefore, even in a case where the ROI is set in a range in which motion occurs, it is possible to move the ROI to an appropriate position in accordance with the motion.

Herein, there will be described a comparative example where no NAND gate 410 is arranged and no output enable signal EN_OUT is supplied to each pixel.

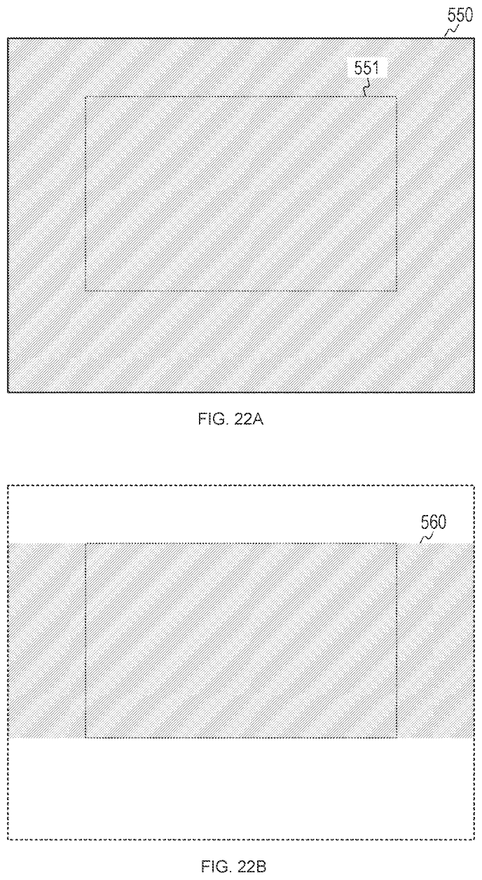

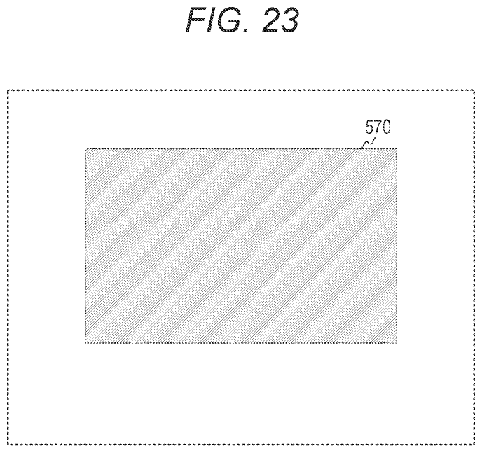

FIG. 22 illustrates image data in which an ROI is set and image data transferred to the signal processing unit 250 in the comparative example. In FIG. 22, a illustrates an example of image data 550 in which the ROI is set. In FIG. 22, b illustrates an example of image data 560 transferred by the repeater 230 to the signal processing unit 250. In b of FIG. 22, an outer dotted line indicates an outer periphery of the image data before the ROI is set.

As illustrated in a of FIG. 22, a rectangular ROI 551 is set in the image data 550. In this case, the vertical drive circuit 213 and the pixel drive circuit 215 of the comparative example drive the pixels to cause the pixels to output pixel data in the ROI to the repeater 230 in the unit of rows. As illustrated in b of FIG. 22, the repeater 230 transfers the image data 560 including the ROI to the signal processing unit 250. Because the image data is output in the unit of rows, columns of the image data 560 include not only columns in the ROI but also columns outside the ROI.

FIG. 23 illustrates an example of the ROI in the comparative example. In FIG. 23, an outer dotted line indicates the outer periphery of the image data before the ROI is set. The signal processing unit 250 of the comparative example holds the image data 560 output in the unit of rows in the frame memory or the like and extracts pixel data in an ROI 570 in the unit of columns from the image data 560. The signal processing unit 250 of the comparative example performs various kinds of signal processing such as image recognition processing on the extracted ROI 570.

As illustrated in FIGS. 22 and 23, in the comparative example where no NAND gate 410 is provided, the vertical drive circuit 213 cannot output pixel data to be processed in the ROI to the repeater 230 in the unit of pixels. Therefore, the vertical drive circuit 213 and the pixel drive circuit 215 drive the pixels to cause the pixels to output the pixel data to be processed to the repeater 230 in the unit of rows. Then, the repeater 230 needs to transfer the pixel data output in the unit of rows to the signal processing unit 250, and the signal processing unit 250 needs to extract the pixel data to be processed in the unit of columns. In this configuration, the amount of data to be transferred to the signal processing unit 250 increases as the number of columns increases, which decreases a processing speed of the signal processing unit 250. Therefore, the solid-state imaging element 200 of the comparative example can realize only a frame rate of, for example, several hundreds of frames per second (fps).

Meanwhile, as illustrated in FIGS. 20 and 21, in the solid-state imaging element 200 including the NAND gates 410, the vertical drive circuit 213 can output the pixel data to be processed to the repeater 230 in the unit of pixels in response to the output enable signals EN_OUT. Thus, it is unnecessary to perform processing in which the signal processing unit 250 holds image data output in the unit of rows in the frame memory or the like and extracts pixel data to be processed in the unit of columns. Therefore, the processing speed of the signal processing unit 250 can be improved by an amount of the processing. With this improvement in processing speed, the solid-state imaging element 200 can capture and process frames at an extremely high frame rate of, for example, tens of thousands of frames per second (fps).

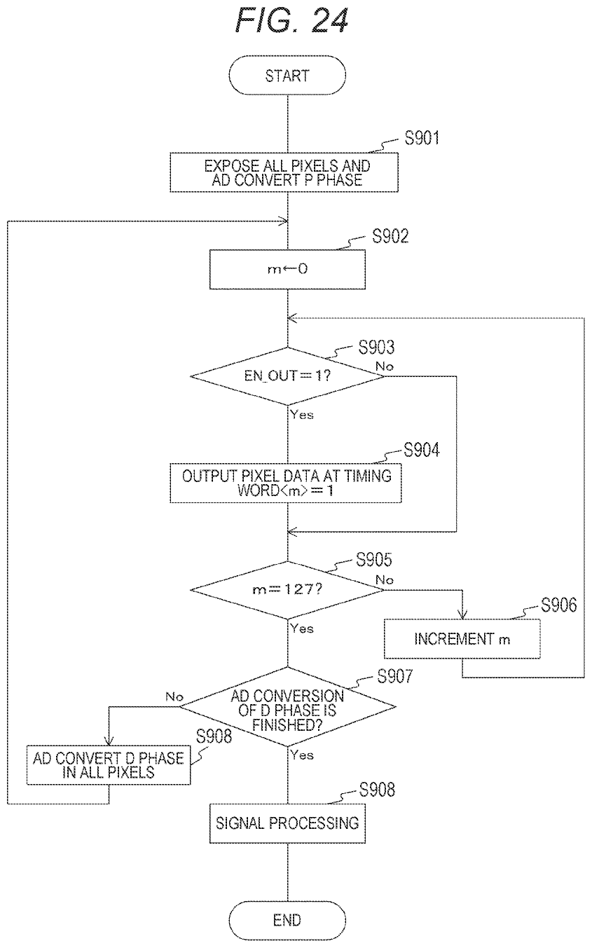

FIG. 24 is a flowchart showing an example of an operation of the solid-state imaging element 200 in the first embodiment of the present technology. The operation is started when, for example, a predetermined application for capturing image data is executed.

The pixel drive circuit 215 and the vertical drive circuit 213 drive each pixel to expose all the pixels and AD convert the P phase (step S901). The vertical drive circuit 213 initializes m to “0” (step S902).

In each cluster 217, the m-th pixel determines whether or not an output enable signal EN_OUT corresponding to the pixel is “1” (i.e., enabled) (step S903). In a case where the corresponding output enable signal EN_OUT is “1” (step S903: Yes), the m-th pixel outputs pixel data to the repeater 230 at a timing at which the output timing signal WORD<m> becomes “1” (step S904).

In a case where the output enable signal EN_OUT is not “1” (step S903: No) or after step S904, the vertical drive circuit 213 determines whether or not m is “127” (step S905). In a case where m is not “127” (step S905: No), the vertical drive circuit 213 increments m (step S906), and step S903 and the subsequent steps are repeated.

In a case where m is “127” (step S905: Yes), the vertical drive circuit 213 determines whether or not conversion of the D phase has been completed (step S907). In a case where the conversion of the D phase has not been completed (step S907: No), the pixel drive circuit 215 and the vertical drive circuit 213 drive each pixel to cause the pixel to generate the D phase, AD convert the D phase, and set m to “0” as in the conversion of the P phase (step S908). Then, the vertical drive circuit 213 repeats step S902 and the subsequent steps.

In a case where the conversion of the D phase has been completed (step S907: Yes), the signal processing unit 250 performs signal processing such as CDS processing and image recognition processing on the transferred pixel data (step S908). After step S908, the solid-state imaging element 200 terminates an operation of capturing and processing image data.

In a case where a plurality of pieces of image data is continuously captured, the processing in steps S901 to S908 is repeatedly executed in synchronization with a vertical synchronization signal VSYNC.

As described above, according to the first embodiment of the present technology, in a case where output is set to be enabled in response to output enable signals EN_OUT, the pixels 300 output pixel data, and therefore the vertical drive circuit 213 can output pixel data to be processed in the unit of pixels. Therefore, it is possible to reduce a throughput of the signal processing unit 250 and improve the processing speed thereof, as compared with a case where pixel data to be processed is output to the signal processing unit 250 in the unit of rows.

### 2. Second Embodiment

In the first embodiment described above, the signal processing unit 250 processes pixel data in the ROI. However, the throughput of the signal processing unit 250 increases as the number of pixels in the ROI increases, which may decrease the processing speed. The solid-state imaging element 200 of a second embodiment is different from that of the first embodiment in that a plurality of signal processing units processes pixel data in parallel.

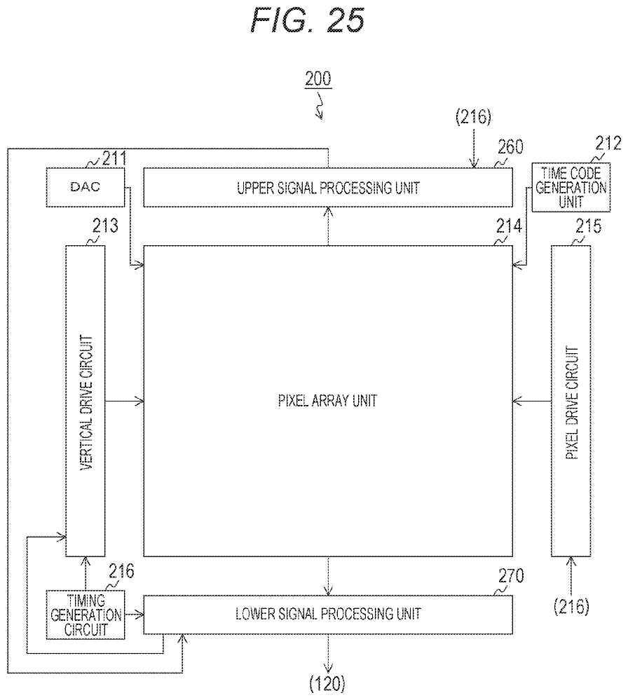

FIG. 25 is a block diagram showing a configuration example of the solid-state imaging element 200 in the second embodiment of the present technology. The solid-state imaging element 200 of the second embodiment is different from that of the first embodiment in that an upper signal processing unit 260 and a lower signal processing unit 270 are provided instead of the signal processing unit 250.

The upper signal processing unit 260 performs CDS processing on pixel data output from a part of a plurality of clusters (e.g., clusters in even columns). The upper signal processing unit 260 supplies the processed pixel data to the lower signal processing unit 270. Note that the upper signal processing unit 260 is an example of a first signal processing unit recited in the claims.

The lower signal processing unit 270 performs CDS processing on pixel data output from the rest of the plurality of clusters (e.g., clusters in odd columns). The lower signal processing unit 270 arrays the pixel data subjected to the CDS processing and supplied from the upper signal processing unit 260 and the pixel data subjected to the CDS processing by the lower signal processing unit 270 itself, thereby generating image data. Then, the lower signal processing unit 270 further performs subsequent processing such as image recognition processing and outputs the processed data. Note that the lower signal processing unit 270 is an example of a second signal processing unit recited in the claims.

As illustrated in FIG. 25, the upper signal processing unit 260 and the lower signal processing unit 270 process pixel data in parallel. This makes it possible to improve the processing speed, as compared with the first embodiment in which only the signal processing unit 250 processes pixel data.

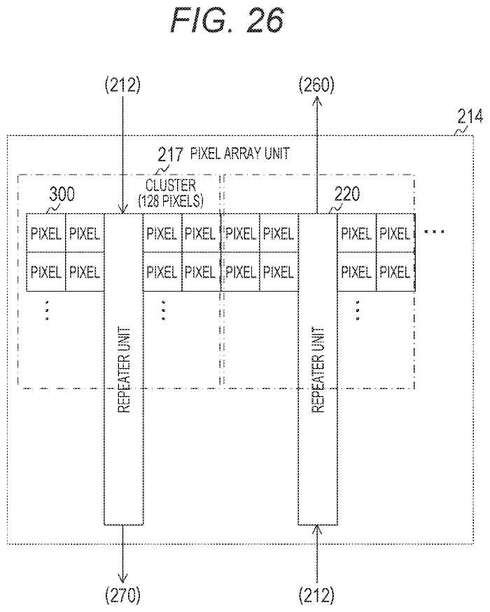

FIG. 26 is a plan view showing a configuration example of the pixel array unit 214 in the second embodiment of the present technology. The repeater units 220 of the clusters 217 in odd columns, such as the first column, transfer pixel data to the lower signal processing unit 270. Meanwhile, the repeater units 220 of the clusters 217 in even columns, such as the second column, transfer pixel data to the upper signal processing unit 260.

As described above, according to the second embodiment of the present technology, the upper signal processing unit 260 and the lower signal processing unit 270 process the odd columns and the even columns in parallel. This makes it possible to improve the processing speed, as compared with a case where only the signal processing unit 250 processes the columns.

<3. Examples of Application to Moving Objects>

The technology according to the present disclosure (present technology) is applicable to various products. For example, the technology according to the present disclosure may be realized as an apparatus to be mounted on any type of moving objects such as an automobile, an electric vehicle, a hybrid electric vehicle, a motorcycle, a bicycle, personal mobility, an airplane, a drone, a ship, and a robot.

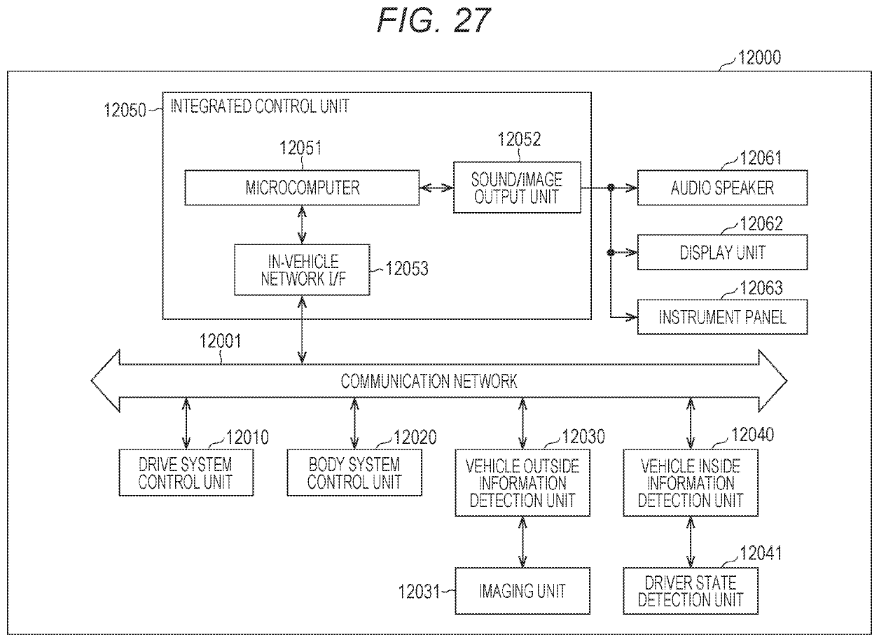

FIG. 27 is a block diagram showing a schematic configuration example of a vehicle control system that is an example of a moving object control system to which the technology according to the present disclosure is applicable.

A vehicle control system 12000 includes a plurality of electronic control units connected via a communication network 12001. In the example of FIG. 27, the vehicle control system 12000 includes a drive system control unit 12010, a body system control unit 12020, a vehicle outside information detection unit 12030, a vehicle inside information detection unit 12040, and an integrated control unit 12050. Further, the integrated control unit 12050 includes, as a functional configuration, a microcomputer 12051, a sound/image output unit 12052, and an in-vehicle network interface (I/F) 12053.

The drive system control unit 12010 controls operations of devices related to a drive system of a vehicle in accordance with various programs. For example, the drive system control unit 12010 functions as a control device for a driving force generator for generating driving force of the vehicle, such as an internal combustion engine or a driving motor, a driving force transmission mechanism for transmitting driving force to wheels, a steering mechanism for adjusting a steering angle of the vehicle, a braking device for generating braking force of the vehicle, and the like.

The body system control unit 12020 controls operations of various devices mounted on a vehicle body in accordance with various programs. For example, the body system control unit 12020 functions as a control device for a keyless entry system, a smart key system, a power window device, or various lamps such as a headlamp, a back lamp, a brake lamp, a blinker, and a fog lamp. In this case, radio waves transmitted from a portable device that substitutes for a key or signals of various switches can be input to the body system control unit 12020. The body system control unit 12020 accepts input of those radio waves or signals and controls a door lock device, the power window device, the lamps, and the like of the vehicle.

The vehicle outside information detection unit 12030 detects information regarding outside of the vehicle on which the vehicle control system 12000 is mounted. For example, the vehicle outside information detection unit 12030 is connected to an imaging unit 12031. The vehicle outside information detection unit 12030 causes the imaging unit 12031 to capture an image of the outside of the vehicle and receives the captured image. On the basis of the received image, the vehicle outside information detection unit 12030 may perform processing of detecting an object such as a person, a vehicle, an obstacle, a sign, or a character on a road surface or processing of detecting a distance therefrom.

The imaging unit 12031 is an optical sensor that receives light and outputs an electrical signal corresponding to an amount of the received light. The imaging unit 12031 can output the electrical signal as an image or can also output the electrical signal as distance measurement information. Further, the light received by the imaging unit 12031 may be visible light or invisible light such as infrared rays.

The vehicle inside information detection unit 12040 detects information regarding inside of the vehicle. For example, the vehicle inside information detection unit 12040 is connected to a driver state detection unit 12041 that detects a state of a driver. The driver state detection unit 12041 includes, for example, a camera that captures an image of the driver, and, on the basis of detection information input from the driver state detection unit 12041, the vehicle inside information detection unit 12040 may calculate a degree of fatigue or concentration of the driver or determine whether or not the driver falls asleep.

The microcomputer 12051 can calculate a control target value of the driving force generator, the steering mechanism, or the braking device on the basis of the information regarding the inside or outside of the vehicle acquired by the vehicle outside information detection unit 12030 or the vehicle inside information detection unit 12040, and output a control command to the drive system control unit 12010. For example, the microcomputer 12051 can perform cooperative control for the purpose of realizing functions of an advanced driver assistance system (ADAS) including collision avoidance or impact attenuation of vehicles, following traveling based on a following distance, vehicle speed maintenance traveling, vehicle collision warning, vehicle lane departure warning, and the like.

Further, the microcomputer 12051 can perform cooperative control for the purpose of autonomous driving in which the vehicle autonomously travels without depending on the driver's operation or for other purposes by controlling the driving force generator, the steering mechanism, the braking device, or the like on the basis of information regarding surroundings of the vehicle acquired by the vehicle outside information detection unit 12030 or the vehicle inside information detection unit 12040.

Further, the microcomputer 12051 can output a control command to the body system control unit 12020 on the basis of the information regarding the outside of the vehicle acquired by the vehicle outside information detection unit 12030. For example, the microcomputer 12051 can perform cooperative control for the purpose of glare protection by, for example, controlling the headlamp in accordance with a position of a preceding vehicle or oncoming vehicle detected by the vehicle outside information detection unit 12030 to switch a high beam to a low beam.

The sound/image output unit 12052 transmits an output signal of at least one of sound or image to an output device capable of visually or aurally notifying a vehicle passenger or the outside of the vehicle of information. The example of FIG. 27 shows an audio speaker 12061, a display unit 12062, and an instrument panel 12063 as examples of the output device. The display unit 12062 may include, for example, at least one of an on-board display or a head-up display.

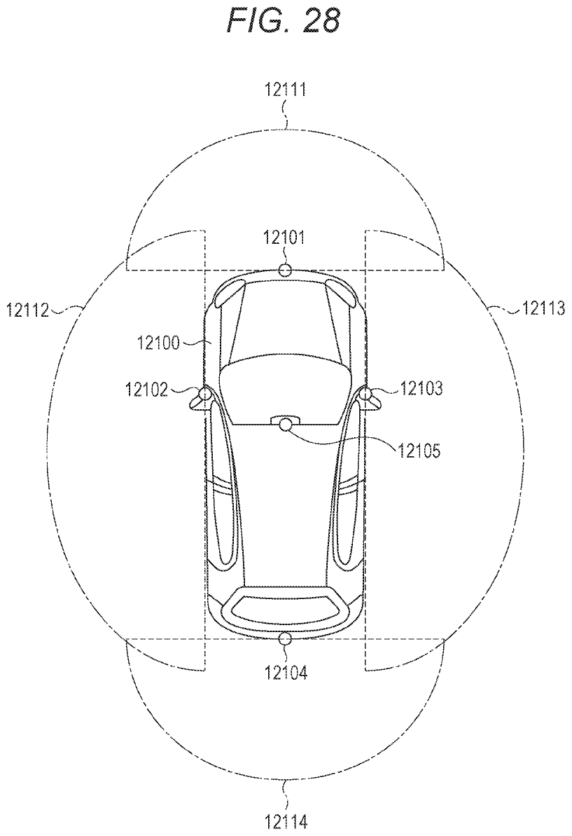

FIG. 28 shows an example of an installation position of the imaging unit 12031.

In FIG. 28, the imaging unit 12031 includes imaging units 12101, 12102, 12103, 12104, and 12105.

The imaging units 12101, 12102, 12103, 12104, and 12105 are provided at, for example, positions such as a front nose, a side mirror, a rear bumper, and a back door of the vehicle 12100 and an upper part of a windshield in the interior of the vehicle. The imaging unit 12101 provided at the front nose and the imaging unit 12105 provided at the upper part of the windshield in the interior of the vehicle mainly acquire images of a front view of the vehicle 12100. The imaging units 12102 and 12103 provided at the side mirrors mainly acquire images of side views of the vehicle 12100. The imaging unit 12104 provided at the rear bumper or back door mainly acquires an image of a rear view of the vehicle 12100. The imaging unit 12105 provided at the upper part of the windshield in the interior of the vehicle is mainly used for detecting a preceding vehicle, a pedestrian, an obstacle, a traffic light, a traffic sign, a lane, or the like.

Note that FIG. 28 shows examples of imaging ranges of the imaging units 12101 to 12104. An imaging range 12111 indicates the imaging range of the imaging unit 12101 provided at the front nose. Imaging ranges 12112 and 12113 indicate the respective imaging ranges of the imaging units 12102 and 12103 provided at the side mirrors. An imaging range 12114 indicates the imaging range of the imaging unit 12104 provided at the rear bumper or back door. For example, an overhead image of the vehicle 12100 viewed from above is obtained by superimposing image data captured by the imaging units 12101 to 12104.

At least one of the imaging units 12101 to 12104 may have a function of acquiring distance information. For example, at least one of the imaging units 12101 to 12104 may be a stereo camera including a plurality of imaging elements or may be an imaging element including pixels for phase difference detection.

For example, on the basis of distance information obtained from the imaging units 12101 to 12104, the microcomputer 12051 obtains a distance from each three-dimensional object within the imaging ranges 12111 to 12114 and a temporal change in this distance (relative speed to the vehicle 12100) and can therefore particularly extract, as a preceding vehicle, the closest three-dimensional object existing on a traveling path of the vehicle 12100 and travelling at a predetermined speed (e.g., 0 km/h or more) in substantially the same direction as that of the vehicle 12100. Further, the microcomputer 12051 can set a following distance from the preceding vehicle to be secured in advance and perform automatic brake control (including following stop control), automatic acceleration control (including following start control), and the like. Thus, it is possible to perform cooperative control for the purpose of autonomous driving in which the vehicle autonomously travels without depending on the driver's operation or for other purposes.

For example, on the basis of the distance information obtained from the imaging units 12101 to 12104, the microcomputer 12051 can classify three-dimensional object data regarding three-dimensional objects into two-wheeled vehicles, standard vehicles, large vehicles, pedestrians, power poles, and other three-dimensional objects, extract the three-dimensional object data, and therefore use the three-dimensional object data in order to automatically avoid obstacles. For example, the microcomputer 12051 identifies obstacles around the vehicle 12100 as obstacles that are noticeable for the driver of the vehicle 12100 and obstacles that are hardly noticeable therefor. Further, the microcomputer 12051 determines a collision risk indicating a risk of collision with each obstacle, and, when the collision risk is equal to or larger than a set value, i.e., in a state in which collision may occur, the microcomputer 12051 can perform driving assistance for collision avoidance by outputting an alarm to the driver via the audio speaker 12061 or the display unit 12062 or by performing forced deceleration or avoidance steering via the drive system control unit 12010.

At least one of the imaging units 12101 to 12104 may be an infrared camera that detects infrared rays. For example, the microcomputer 12051 can recognize a pedestrian by determining whether or not a pedestrian exists in the captured images of the imaging units 12101 to 12104. Such recognition of the pedestrian is carried out by performing, for example, a procedure for extracting feature points in the captured images of the imaging units 12101 to 12104 serving as infrared cameras and a procedure for performing pattern matching processing on a series of the feature points indicating an outline of an object and determining whether or not the object is a pedestrian. When the microcomputer 12051 determines that a pedestrian exists in the captured images of the imaging units 12101 to 12104 and recognizes the pedestrian, the sound/image output unit 12052 controls the display unit 12062 so that a rectangular outline for emphasis is displayed to be superimposed on the recognized pedestrian. Further, the sound/image output unit 12052 may control the display unit 12062 so that an icon or the like indicating the pedestrian is displayed at a desired position.

Hereinabove, an example of the vehicle control system to which the technology according to the present disclosure is applicable has been described. The technology according to the present disclosure is applicable to, for example, the imaging unit 12031 in the above configuration. Specifically, the imaging apparatus 100 in FIG. 1 is applicable to the imaging unit 12031. By applying the technology according to the present disclosure to the imaging unit 12031, it is possible to improve a frame rate. This makes it possible to improve image quality of a moving image and reduce driver fatigue.

Note that the above embodiments show examples for embodying the present technology, and the matters in the embodiments and the matters specifying the invention in the claims have a corresponding relationship. Similarly, the matters specifying the invention in the claims and the matters in the embodiments of the present technology represented by the same names as those in the matters specifying the invention in the claims have a corresponding relationship. However, the present technology is not limited to the embodiments, and can be embodied by applying various modification examples to the embodiments within the gist thereof.

Note that the effects described in this specification are merely examples and are not limited, and other effects may be exerted.

Note that the present technology may also have the following configurations.

(1) A solid-state imaging element including:

a repeater that is connected to a cluster in which a predetermined number of pixels are arrayed and transfers digital signals indicating a time within a predetermined period;

a vertical drive circuit that supplies an output timing signal indicating an output timing of each of the predetermined number of pixels and an output enable signal indicating whether or not output of the digital signal is enabled for each of the pixels;

a comparator that compares an analog signal corresponding to an amount of exposure with a reference signal varying during the predetermined period and outputs a comparison result;

a latch circuit that acquires the digital signal from the repeater and holds the digital signal;

a latch control circuit that controls the latch circuit to cause the latch circuit to hold the digital signal when the comparison result is inverted and controls the latch circuit to cause the latch circuit to output the digital signal to the repeater at the timing indicated by the output timing signal; and

an enable control unit that supplies the output timing signal to the latch control circuit in a case where the output of the digital signal is set to be enabled in response to the output enable signal.

(2) The solid-state imaging element according to (1), further including:

a repeater that is connected to a predetermined number of pixels and transfers the digital signals; and

a vertical drive circuit that sequentially drives the predetermined number of pixels to cause the predetermined number of pixels to output the digital signals in response to the output timing signals, in which:

the repeater and the predetermined number of pixels are arranged in each of a plurality of clusters; and

the comparator, the latch circuit, the latch control circuit, and the enable control unit are arranged in each of the predetermined number of pixels.

(3) The solid-state imaging element according to (1) or (2), further including

a signal processing unit that performs predetermined signal processing on the digital signals transferred by the repeater.

(4) The solid-state imaging element according to (3), in which:

the signal processing unit includes first and second signal processing units;

the first signal processing unit performs the signal processing on the digital signals output from a part of the plurality of clusters; and

the second signal processing unit performs the signal processing on the digital signals output from the rest of the plurality of clusters.

(5) The solid-state imaging element according to (3) or (4), in which

the signal processing unit includes

a signal processing circuit that performs predetermined signal processing on the output digital signals to generate image data, and

a region-of-interest setting unit that sets, as a region of interest, a region of the image data to which the digital signals are to be output.

(6) The solid-state imaging element according to (5), in which

the signal processing unit further includes

a motion vector detection unit that detects, for each subject in the image data, a motion vector indicating a moving direction of the subject, and

a region-of-interest prediction unit that predicts a position of the region of interest in image data to be generated next on the basis of the motion vector.

(7) An imaging apparatus including:

a repeater that is connected to a cluster in which a predetermined number of pixels are arrayed and transfers digital signals indicating a time within a predetermined period;

a vertical drive circuit that supplies an output timing signal indicating an output timing of each of the predetermined number of pixels and an output enable signal indicating whether or not output of the digital signal is enabled for each of the pixels;

a comparator that compares an analog signal corresponding to an amount of exposure with a reference signal varying during the predetermined period and outputs a comparison result;

a latch circuit that acquires the digital signal from the repeater and holds the digital signal;

a latch control circuit that controls the latch circuit to cause the latch circuit to hold the digital signal when the comparison result is inverted and controls the latch circuit to cause the latch circuit to output the digital signal to the repeater at the timing indicated by the output timing signal;

an enable control unit that supplies the output timing signal to the latch control circuit in a case where the output of the digital signal is set to be enabled in response to the output enable signal; and

a storage unit that stores image data in which the digital signals are arrayed.

(8) A method of controlling a solid-state imaging element, the method including:

a transfer step of being connected to a cluster in which a predetermined number of pixels are arrayed and transferring digital signals indicating a time within a predetermined period;

a vertical driving step of supplying an output timing signal indicating an output timing of each of the predetermined number of pixels and an output enable signal indicating whether or not output of the digital signal is enabled for each of the pixels;

a comparison step of comparing an analog signal corresponding to an amount of exposure with a reference signal varying during the predetermined period and outputting a comparison result;

a latch step of acquiring the digital signal from the repeater and holding the digital signal;

a latch control step of controlling the latch circuit to cause the latch circuit to hold the digital signal when the comparison result is inverted and controlling the latch circuit to cause the latch circuit to output the digital signal to the repeater at the timing indicated by the output timing signal; and

an enable control step of supplying the output timing signal to the latch control circuit in a case where the output of the digital signal is set to be enabled in response to the output enable signal.

### REFERENCE SIGNS LIST

100 Imaging apparatus
110 Optical unit
120 DSP circuit
130 Display unit
140 Operation unit
150 Bus
160 Frame memory
170 Storage unit
180 Power supply unit
200 Solid-state imaging element
201 Light receiving chip
202 Circuit chip
211 DAC
212 Time code generation unit
213 Vertical drive circuit
214 Pixel array unit
215 Pixel drive circuit
216 Timing generation circuit
217 Cluster
220 Repeater unit
230 Repeater
231 to 234, 241, 242, 422, 423, 432, 433 Inverter
240 Transfer circuit
243 Flip-flop
250 Signal processing unit
251 CDS processing unit
252 Frame memory
253 Motion vector detection unit
254 ROI setting unit
255 Next-frame ROI prediction unit
256 Subsequent-stage processing unit
260 Upper signal processing unit
270 Lower signal processing unit
300 Pixel
305 ADC
310 Pixel circuit
311 Reset transistor
312, 314 Floating diffusion layer
313 FDG transistor
315 Transfer transistor
316 Photoelectric conversion element
317 Charge discharging transistor
320 Comparator
330 Differential input circuit
331, 334, 344, 351, 352 pMOS transistor
332, 335 Differential transistor
333 Current source transistor
340 Positive feedback circuit
341 to 343, 345, 353, 354 nMOS transistor
350 Inverter circuit
400 Latch unit
410 NAND gate
420 Latch control circuit
421 NOR gate
431 Switch
430 Latch circuit
12031 Imaging unit

1. A solid-state imaging element comprising:
a repeater that is connected to a cluster in which a predetermined number of pixels are arrayed and transfers digital signals indicating a time within a predetermined period;
a vertical drive circuit that supplies an output timing signal indicating an output timing of each of the predetermined number of pixels and an output enable signal indicating whether or not output of the digital signal is enabled for each of the pixels;
a comparator that compares an analog signal corresponding to an amount of exposure with a reference signal varying during the predetermined period and outputs a comparison result;
a latch circuit that acquires the digital signal from the repeater and holds the digital signal;
a latch control circuit that controls the latch circuit to cause the latch circuit to hold the digital signal when the comparison result is inverted and controls the latch circuit to cause the latch circuit to output the digital signal to the repeater at the timing indicated by the output timing signal; and
an enable control unit that supplies the output timing signal to the latch control circuit in a case where the output of the digital signal is set to be enabled in response to the output enable signal.

2. The solid-state imaging element according to claim 1, wherein
the comparator, the latch circuit, the latch control circuit, and the enable control unit are arranged in each of the predetermined number of pixels.

3. The solid-state imaging element according to claim 1, further comprising
a signal processing unit that performs predetermined signal processing on the digital signals transferred by the repeater.

4. The solid-state imaging element according to claim 3, wherein:
the signal processing unit includes first and second signal processing units;
the first signal processing unit performs the signal processing on the digital signals output from a part of the plurality of clusters; and
the second signal processing unit performs the signal processing on the digital signals output from the rest of the plurality of clusters.

5. The solid-state imaging element according to claim 3, wherein
the signal processing unit includes
a signal processing circuit that performs predetermined signal processing on the output digital signals to generate image data, and
a region-of-interest setting unit that sets, as a region of interest, a region of the image data to which the digital signals are to be output.

6. The solid-state imaging element according to claim 5, wherein
the signal processing unit further includes
a motion vector detection unit that detects, for each subject in the image data, a motion vector indicating a moving direction of the subject, and
a region-of-interest prediction unit that predicts a position of the region of interest in image data to be generated next on a basis of the motion vector.

7. An imaging apparatus comprising:
a repeater that is connected to a cluster in which a predetermined number of pixels are arrayed and transfers digital signals indicating a time within a predetermined period;
a vertical drive circuit that supplies an output timing signal indicating an output timing of each of the predetermined number of pixels and an output enable signal indicating whether or not output of the digital signal is enabled for each of the pixels;
a comparator that compares an analog signal corresponding to an amount of exposure with a reference signal varying during the predetermined period and outputs a comparison result;
a latch circuit that acquires the digital signal from the repeater and holds the digital signal;
a latch control circuit that controls the latch circuit to cause the latch circuit to hold the digital signal when the comparison result is inverted and controls the latch circuit to cause the latch circuit to output the digital signal to the repeater at the timing indicated by the output timing signal;
an enable control unit that supplies the output timing signal to the latch control circuit in a case where the output of the digital signal is set to be enabled in response to the output enable signal; and
a storage unit that stores image data in which the digital signals are arrayed.

8. A method of controlling a solid-state imaging element, the method comprising:
a transfer step of being connected to a cluster in which a predetermined number of pixels are arrayed and transferring digital signals indicating a time within a predetermined period;
a vertical driving step of supplying an output timing signal indicating an output timing of each of the predetermined number of pixels and an output enable signal indicating whether or not output of the digital signal is enabled for each of the pixels;
a comparison step of comparing an analog signal corresponding to an amount of exposure with a reference signal varying during the predetermined period and outputting a comparison result;
a latch step of acquiring the digital signal from the repeater and holding the digital signal;
a latch control step of controlling the latch circuit to cause the latch circuit to hold the digital signal when the comparison result is inverted and controlling the latch circuit to cause the latch circuit to output the digital signal to the repeater at the timing indicated by the output timing signal; and
an enable control step of supplying the output timing signal to the latch control circuit in a case where the output of the digital signal is set to be enabled in response to the output enable signal.
